(19) United States
(12) Patent Application Publication
(10) Pub. No.: US 2025/0362623 A1
(43) Pub. Date: Nov. 27, 2025

(54) PHOTOLITHOGRAPHY APPARATUS AND METHOD OF OPERATING THE SAME

(71) Applicant: Taiwan Semiconductor Manufacturing Company, Ltd., Hsinchu (TW)

(72) Inventors: Chia-Wei Wang, Taichung City (TW); Po-Ming Shih, Hsinchu (TW); Yi-Chen Li, Taichung City (TW)

(21) Appl. No.: 19/282,132

(22) Filed: Jul. 28, 2025

Related U.S. Application Data
(63) Continuation of application No. 18/889,003, filed on Sep. 18, 2024.
(60) Provisional application No. 63/651,005, filed on May 23, 2024.

(51) Int. Cl. G03F 7/00

(52) U.S. Cl. CPC G03F 7/70966; G03F 7/70591; G03F 7/70741; G03F 7/70983

(57) ABSTRACT

A photolithography apparatus and a method for operating the photolithography apparatus are provided. The method includes steps of receiving a reticle assembly comprising a reticle protected by a pellicle membrane; transporting the reticle assembly to an exposure tool and securing the reticle assembly on a reticle stage of the exposure tool; determining a scanning speed profile based on a risk level rupture of the pellicle membrane; and preforming an exposure operation by driving the reticle stage according to the scanning profile.

### CROSS-REFERENCE TO RELATED APPLICATIONS

This application is a continuation of U.S. patent application Ser. No. 18/889,003, filed Sep. 18, 2024, which claims the benefit of U.S. Provisional Application No. 63/651,005, filed May 23, 2024, the entire disclosures of which are incorporated by reference herein.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the size of the smallest component (or line) that can be created using a fabrication process) has decreased. This scaling-down process generally provides benefits by increasing production efficiency and decreasing associated costs. Such scaling down has also increased the complexity of IC processing and manufacturing. For these advances to be realized, similar developments in IC processing and manufacturing are needed. For example, there is an increasing need to perform lithography processes at higher resolutions.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a flow chart illustrating an embodiment of a method of performing the acceleration and speed management of a photolithography system accounting for the membrane film quality, in accordance with some embodiments of the present disclosure.

FIG. 2 is a schematic diagram of a photolithography apparatus in accordance with some embodiments of the present disclosure.

FIG. 3 is a schematic diagram of an exposure tool in accordance with some embodiments of the present disclosure.

FIG. 4A is a schematic cross-sectional view of a reticle assembly in accordance with some embodiments of the present disclosure.

FIG. 4B is a schematic cross-sectional view of a reticle assembly pod in accordance with some embodiments of the present disclosure.

FIG. 5 illustrates a table showing examples of pellicle membranes in accordance with some embodiments of the present disclosure.

FIG. 6 illustrates an embodiment of a Eop trend chart in accordance with some embodiments of the present disclosure.

FIG. 7 illustrates a chart illustrating a comparison of the deformation with wafers processed in accordance with some embodiments of the present disclosure.

FIG. 8 is a schematic diagram of an inspection tool in accordance with some embodiments of the present disclosure.

FIG. 9 is a schematic diagram of another inspection tool in accordance with some embodiments of the present disclosure.

FIG. 10 is a schematic view of a reticle in accordance with some embodiments of the present disclosure.

FIG. 11 is a schematic plan view of a substrate which is held by a substrate stage in accordance with some embodiments of the present disclosure.

FIG. 12A is a cross-sectional view of an electrostatic chuck and a reticle in accordance with some embodiments of the present disclosure.

FIG. 12B is a schematic view of electrostatic chuck including electrodes in accordance with some embodiments of the present disclosure.

FIGS. 12C and 12D are cross-sectional view of an electrostatic chuck and a reticle in accordance with some embodiments of the present disclosure.

FIGS. 13A-13L schematically depict an exposure operation performed on some of shot regions on a substrate in accordance with some embodiments of the present disclosure.

FIG. 14 depicts a first scanning speed profile in accordance with some embodiments of the present disclosure.

FIG. 15 illustrates a diagrammatical illustration of a lithography system in accordance with some embodiments of the present disclosure.

FIG. 16 is a flowchart showing a method for operating an exposure tool in accordance with some embodiments of the present disclosure.

FIG. 17 is a flowchart showing a method for operating an exposure tool in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another end point or between two endpoints. All ranges disclosed herein are inclusive of the endpoints, unless specified otherwise.

In photolithography, a photoresist layer is formed on a substrate, and the photoresist layer is subjected to an exposure operation via a reticle. The reticle having a desired pattern is mounted on a reticle stage; a reticle may also be referred to herein as a mask. During the exposure operation, the reticle stage is operable to move the reticle in one or more directions as required for proper alignment of the reticle relative to the substrate. As such, electromagnetic radiation directed to the pattern of the reticle can be projected onto selected areas of the photoresist layer. The electromagnetic radiation may cause a chemical transformation in the selected areas of the photoresist layer. In a subsequent development step, the selected areas or non-selected areas can be removed from the substrate. In such manner, the pattern of the reticle may be transferred to the photoresist layer and thus a patterned photoresist layer is formed. The substrate may then be further processed (e.g., materials may be removed, deposited, doped, etc.) through the patterned photoresist layer, thereby forming a patterned layer (corresponding to the pattern of the reticle) in or on the substrate.

The pattern of the reticle is desired to have minimal defects to increase the production yield. It may be challenging to prevent particles present in the environment from being deposited on the reticle. As a result, a pellicle membrane, or simply pellicle, is sometimes utilized to cover and the reticle. The pellicle may be positioned just below the reticle and allows radiation (e.g., extreme ultraviolet (EUV) light) through. Deflection such as deformity (e.g., outward sagging) of the pellicle membrane may occur. This deformity may be caused by, for example, gravity, weight of foreign material deposited on the pellicle membrane, and/or conditions (e.g., pressure) from the movement of the reticle assembly including the pellicle.

Because of the need to achieve high throughput, the reticle stage (also referred to as a mask chuck or stage) is drivable to move the reticle along a scanning direction at a speed during the exposure operation of the photolithography. The movement at speed, and moreover, the acceleration of the reticle to the speed can provide pressure to the pellicle and cause pellicle deformation including leading to damage such as rupture.

Some embodiments of the present disclosure provide a photolithography apparatus and a method of operating the same. The proposed apparatus includes a control unit configured to provide a scanning speed profile including an acceleration management plan to a reticle stage based on various factors including a deformation range of a pellicle membrane. Hence, the image distortion during exposure can be effectively reduced, and a service life of the pellicle membrane may be increased. The advantages of some embodiments including saving costs caused by retooling the reticle due to damage of the reticle and/or pellicle, an increase in scanner productivity through management of the acceleration and speed.

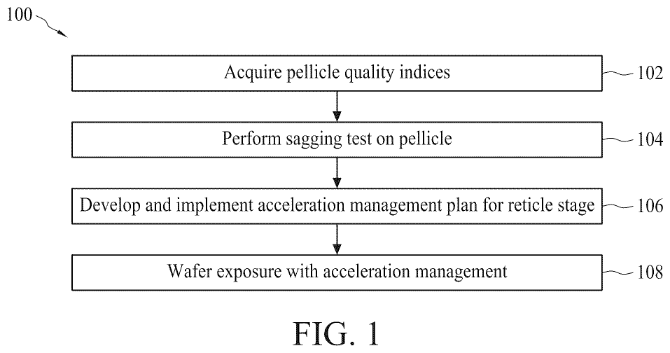

FIG. 1 is a block diagram view of a method 100 of performing the acceleration and speed management of a photolithography system and a reticle stage in particular that accounts for the membrane film quality. The method 100 includes a block 102 where original state indices are acquired. In an embodiment, the state indices acquired include one or more of energy of power (EOP) status, wafer movement (W.M.) status, pellicle type (e.g., membrane film scheme details), original state of the membrane film (e.g., position), and/or other suitable indices. The state indices may be acquired from in-line process data, simulation data, modeling data, experimental data, design databases, process data, reticle data, and the like. In an embodiment, acquiring the pellicle state indices includes block 104. In block 104, a sagging test is performed. The sagging test may be performed on the pellicle to determine its status. The sagging test may be an empirical test to determine a sagging value (e.g., displacement distance in microns) of the pellicle film. Blocks 102 and 104 may be performed simultaneously or in alternating orders. The method 100 then proceeds to block 106 where a scanning speed profile including an acceleration management plan is developed and/or implemented based on the results of block 102 and/or 104. The method 100 then process to block 108 where the wafer is exposed in a photolithography process implementing the scanning speed profile including an acceleration management plan. In an embodiment, implementation of the plan allows for avoiding pellicle damage such as rupture. Each of these blocks are discussed in further detail below.

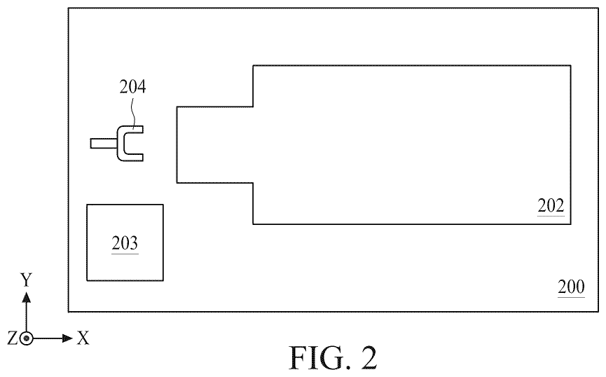

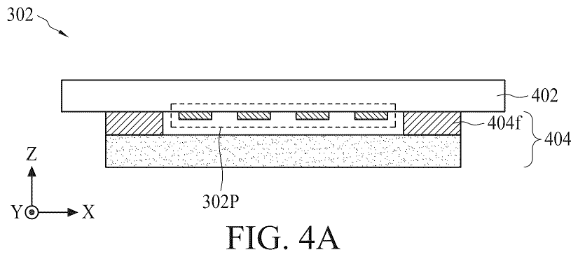

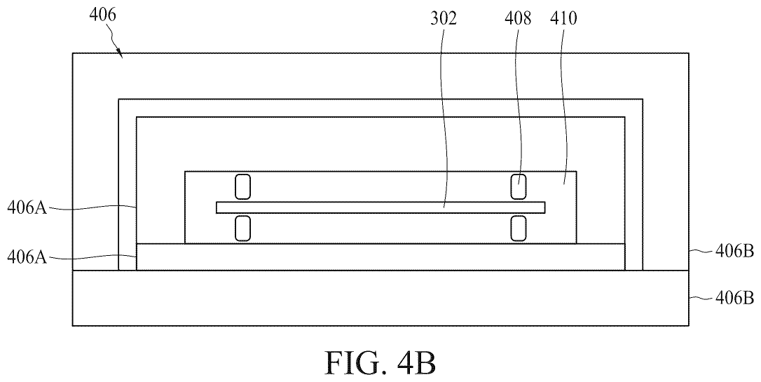

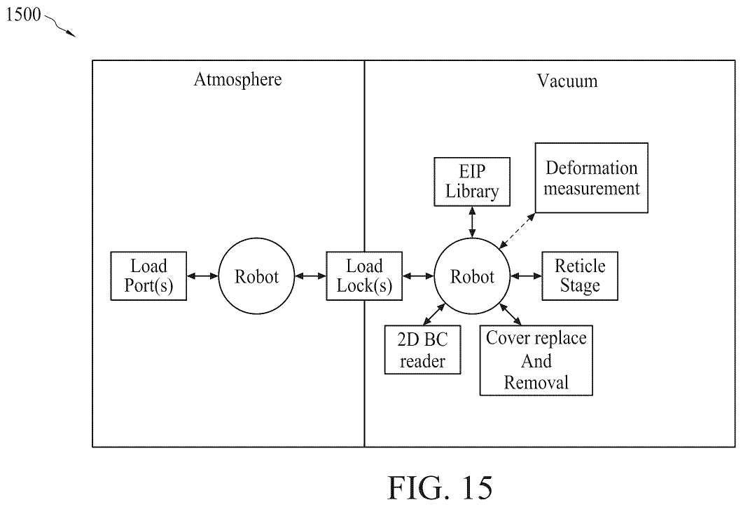

FIG. 2 is a schematic view of a photolithography apparatus 200 in accordance with some embodiments of the present disclosure. The photolithography apparatus 200 includes, for example, an exposure tool 202, an inspection tool 203, and a transport robot 204. In some embodiments, the photolithography apparatus 200 is installed in a cleanroom. Air controlled to a predetermined temperature circulates in the cleanroom to keep an internal temperature of the cleanroom approximately constant or within a predetermined range. See atmosphere. In an embodiment, the photolithography apparatus 200 may be connected to a load-lock chamber (see FIG. 15), which is used when loading and unloading a reticle assembly 302 (e.g., FIG. 4A) into and from the photolithography apparatus 200. The exposure tool 202 is housed in an exposure chamber (not separately shown), while in an embodiment the inspection tool 203 is positioned inside an inspection chamber (not separately shown). In other embodiments, the inspection tool 203 is separate and distinct (e.g., off line) from the exposure tool 202. The transport robot 204 loads and unloads the reticle assembly 302 and transports the reticle assembly 302 between the exposure tool 202 and the inspection tool 203. In some embodiments, the inspection tool 203 can be integrated into the exposure tool 202 to reduce delivery time of the reticle assemble 302 between the exposure tool 202 and the inspection tool 203.

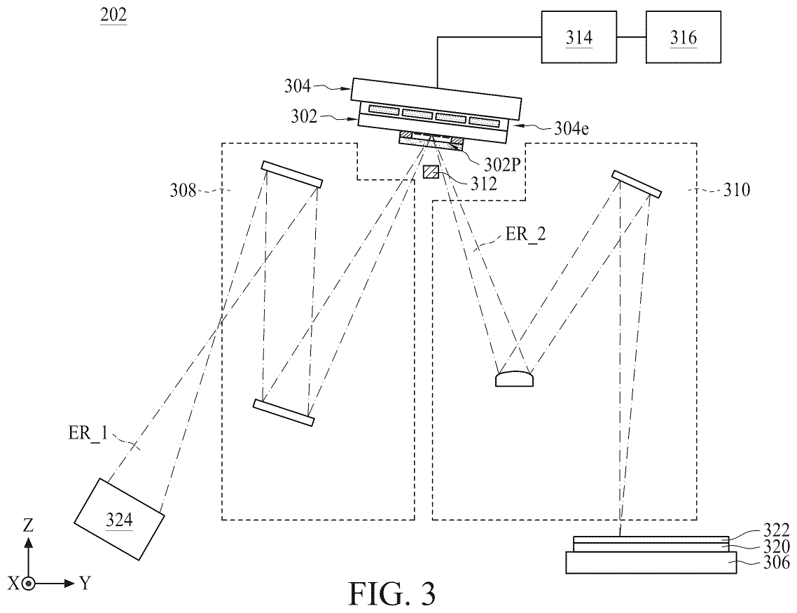

FIG. 3 is a schematic view of the exposure tool 202 in accordance with some embodiments of the present disclosure. The exposure tool 202 can be used, for example, in the manufacture of integrated circuits. The reticle assembly 302 may be used to provide a desired pattern 302P to be formed on a material layer of the integrated circuit. In an exposure operation, the reticle assembly 302 is irradiated by an electromagnetic radiation ER_1, wherein the pattern 302P of the reticle assembly 302 reflects and patterns the electromagnetic radiation ER_1 to form a patterned electromagnetic radiation ER_2. The patterned electromagnetic radiation ER_2 is directed onto a photoresist layer 322 provided over a substrate 320.

In some embodiments, the exposure tool 202 includes a radiation source 324, a reticle stage 304, a substrate stage 306, an illumination optical module 308, a projection optical module 310, a detector 312, a database 316, and a control unit 314. The radiation source 324 is configured to generate the electromagnetic radiation ER_1. In some embodiments, the reticle stage 304 secures the reticle assembly 302 and provides accurate positioning and movement of the reticle assembly 302 during the exposure operation. In some embodiments, the substrate stage 306 supports the substrate 320 and is capable of moving the substrate 320 with respect to the reticle assembly 302. In some embodiments, the illumination optical module 308 is used to direct the electromagnetic radiation ER_1 generated by the radiation source 324 to the reticle assembly 302. In some embodiments, the projection optical module 310 directs the patterned electromagnetic radiation ER_2, carrying the image of the pattern on the reticle assembly 302, onto the photoresist layer 322.

In some embodiments, the detector 312 is capable of providing information regarding the electromagnetic radiation ER_1 and/or patterned electromagnetic radiation ER_2 to the control unit 314. In some embodiments, the database 316 contains data for operating the exposure tool 202 and data associated with the reticle assembly 302 and the substrate 320. In some embodiments, the control unit 314 is electrically coupled to the reticle stage 304, the detector 312, the database 316, and the inspection tool 203 shown in FIG. 3. The control unit 314 may receive information from the radiation source 324, the reticle stage 304, the substrate stage 306, the detector 312, the database 316 and the inspection tool 203, and transmit control data to the radiation source 324, the reticle stage 304 and the substrate stage 306. In some embodiments, the control unit 314 is configured to control a scanning speed of the reticle stage 304 based on the information provided by the radiation source 324, the detector 312, the database 316, and the inspection tool 203, and the control details are discussed below.

The radiation source 324 may be any suitable optical source, such as an extreme ultraviolet (EUV) source. The EUV source may generate an EUV radiation having a wavelength between 1 nm and about 100 nm. In some embodiments, the EUV source generates the EUV radiation with a wavelength centered at about 13.5 nm. The EUV radiation may be formed with a pulse-type waveform, and the radiation energy may be represented by a total energy of the EUV pulses applied during the entire exposure operation in the unit of Joule.

Because gas molecules tend to absorb the EUV radiation, an optical path through which the EUV radiation radiates is maintained in a vacuum environment to prevent a loss of an intensity of the EUV. In some embodiments, when the exposure tool 202 adopts the EUV radiation, the exposure tool 202 is housed in and operated in the vacuum environment. In some embodiments, when the exposure tool 202 includes the EUV source, the reticle 302 is a reflective reticle. In other embodiments, the radiation source 324 may include an optical source selected from the group consisting of an ultraviolet (UV) source, a deep UV (DUV) source, and an X-ray source. The radiation source 324 may alternatively include a particle source selected from the group consisting of an electron beam (E-beam) source, an ion beam source, and a plasma source.

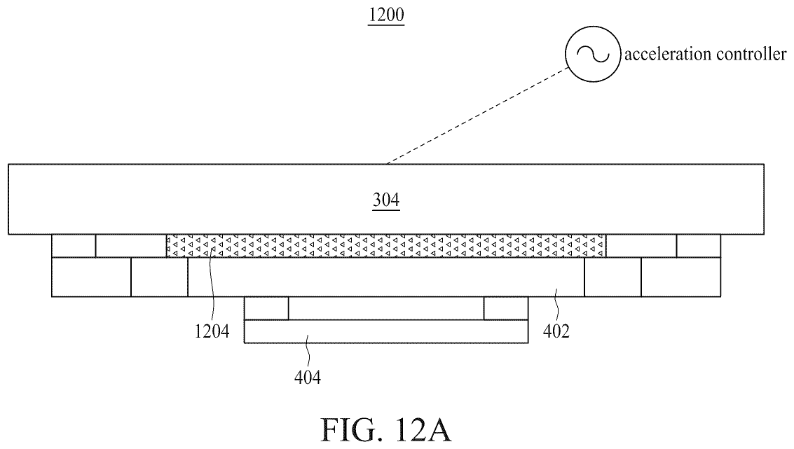

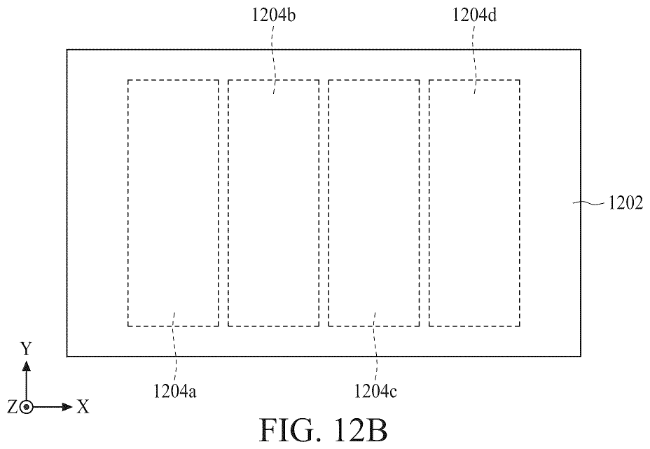

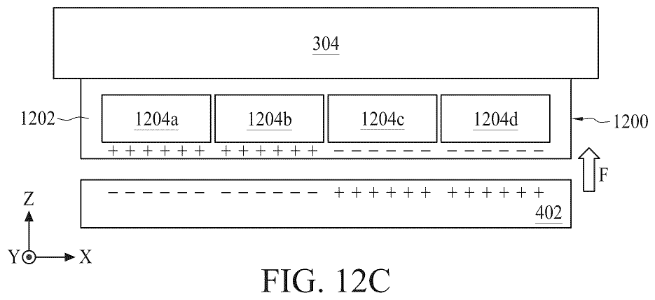

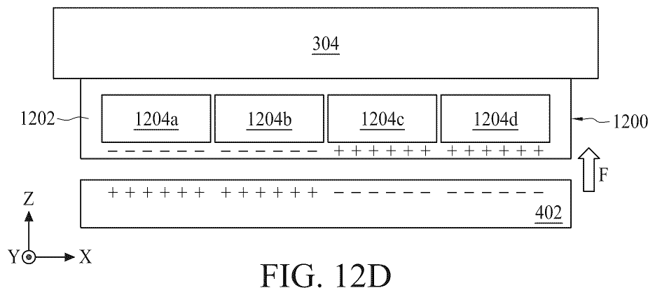

The reticle assembly 302 is held on the reticle stage 304. In some embodiments, the reticle assembly 302 is held on the reticle stage 304 by an electrostatic force. For example, the reticle stage 304 includes an electrostatic chuck 304e to secure the reticle assembly 302 in place during the exposure operation. The chuck is discussed in further detail below with reference to FIGS. 12A-12D. The reticle stage 304 is operable to move the reticle assembly 302 in at least one scanning direction. The reticle stage 304 also has a fine adjustment mechanism for positioning the reticle assembly 302 relative to the substrate 320 for accurate exposure. In some embodiments, the reticle stage 304 is designed and operable for translational, rotational and/or tilting movements.

In some embodiments, the reticle 302 and the substrate 320 are moved synchronously during the exposure operation. The substrate stage 306 may have a movement speed proportional to the scanning speed of the reticle stage 304.

During the exposure operation, a portion of the reticle assembly 302 is illuminated by the electromagnetic radiation ER_1. The illumination optical module 308 may be utilized to uniform the intensity distribution of the electromagnetic radiation ER_1. The illumination optical module 308 may serve to shape the contour of the electromagnetic radiation ER_1 emerging from the radiation source 324. For example, when the electromagnetic radiation ER_1 passes through the illumination optical module 308, it is shaped into a designed profile. It is therefore the patterned electromagnetic radiation ER_2 that has the corresponding profile. In embodiments where the exposure tool 202 includes the EUV source, the illumination optical module 308 includes various reflective optical components, such as flat mirrors and/or multiple mirrors including reflective surfaces with convex or concave spherical shapes or aspheric shapes.

The projection optical module 310 directs the patterned electromagnetic radiation ER_2, carrying an image of an irradiated portion of the reticle assembly 302, onto the photoresist layer 322. The projection optical module 310 may have a magnification factor (such as ¼ times). The magnification factor refers to a ratio of the dimensions (for example, an area) of the electromagnetic radiation ER_1 at the reticle assembly 302 to the corresponding dimensions of the patterned electromagnetic radiation ER_2 at the substrate 320. The projection optical module 310 may have a same magnification in the X- and Y-directions. In order to achieve synchronized moving of the reticle stage 304 and the substrate stage 306 during the exposure operation, when the magnification factor of the projection optical module 310 is ¼, the movement speed of the substrate stage 306 during the exposure operation is ½ of the scanning speed of the reticle stage 304. In embodiments where the exposure tool 202 includes the EUV source, the projection optical module 310 includes various reflective optical components such as flat mirrors and/or multiple mirrors including reflective surface with convex and concave spherical shapes or aspheric shapes.

FIG. 4A is a schematic cross-sectional view of the reticle assembly 302 in accordance with some embodiments of the present disclosure. The reticle assembly 302 may be substantially similar to as discussed above with reference to FIG. 3. Referring to FIG. 4A, the reticle assembly 302 includes a reticle 402 and a pellicle 404. The pattern 302P is formed on a surface of the reticle 402. The reticle 402 may be used to reproducibly imprint hundreds or thousands of substrates 320 given a good condition of the reticle 402 and the pellicle 404. Although efforts may be made to maintain a clean environment inside the exposure tool 202, particles may still be present inside the photolithography apparatus 200. Particles falling on the reticle 402 may disadvantageously affect the pattern 302P that is carried by the patterned electromagnetic radiation ER_2 and transferred to the substrate 320, and may cause yield issues and quality concerns. In order to protect the reticle 402 from particle contamination, the pattern of the reticle 402 is protected by the pellicle 404.

The pellicle 404 includes along with the pellicle membrane, a frame 404f which holds the pellicle membrane in place. The frame 404f may be disposed at an edge portion of the pellicle membrane 404. The pellicle membrane may be adhered to the frame 404f with glues or other adhesives. The frame 404f may be any material that has a high mechanical strength, low tendency to attract dust, and is lightweight. Hard plastics and materials such as aluminum or an aluminum alloy may be suitable materials for the frame 404f. The pellicle membrane 404 is designed to have a high transmittance for the electromagnetic radiation ER_1 and low reflectivity of electromagnetic radiation.

The pellicle 404, by way of the frame 404f, is attached to the reticle 402 and surrounds the pattern on the reticle 402. Therefore, contamination which would otherwise be deposited on the pattern 302P of the reticle 402 is blocked by the pellicle membrane 404. In addition, the frame 404f is also utilized to position the pellicle membrane 404 at a sufficient defocus distance from the pattern such that any particle on the pellicle membrane 404 will be out of focus during the exposure operation, and therefore will not be projected onto the target substrate.

In order to minimize EUV transmission loss, it may be desirable to form the pellicle membrane 404 as thin as possible. In some embodiments, the pellicle membrane 404 has a thickness in a range between about 15 nm and about 50 nm. The pellicle membrane 404 may be a multi-layer structure. In some embodiments, the multi-layer structure is made of a combination of different materials selected for particular purposes (e.g., heat dissipation, strength, uniformity, durability, stability, and the like) and arranged in an order as desired.

Referring to FIG. 4B, illustrated is a reticle pod 406 in cross-sectional view. The reticle pod 406 provides for a reticle (e.g., reticle assembly 302) storage, transport, and protection while loading into a lithography system such as the photolithography apparatus 200. The reticle pod 406 includes two pods, an inner pod 406A (also referred to as an inner pod (EIP)) and an outer pod 406B (also referred to as an outer pod (EOP)). Restraining mechanisms 408 hold the reticle assembly 302. While not illustrated, the reticle assembly is positioned face-down and includes the pellicle arranged over the patterned surface as discussed above. For example, the pellicle is disposed between the restraining mechanisms 408 below the reticle assembly 302. The restraining mechanisms 408 may be a clamp, a groove, a pin, a fixation block, a spring, or other suitable means. An internal space 410 surrounds the reticle assembly 302. The inner pod 406A may be made of metal materials such as stainless steel, and outer pod 406B may be made of plastic.

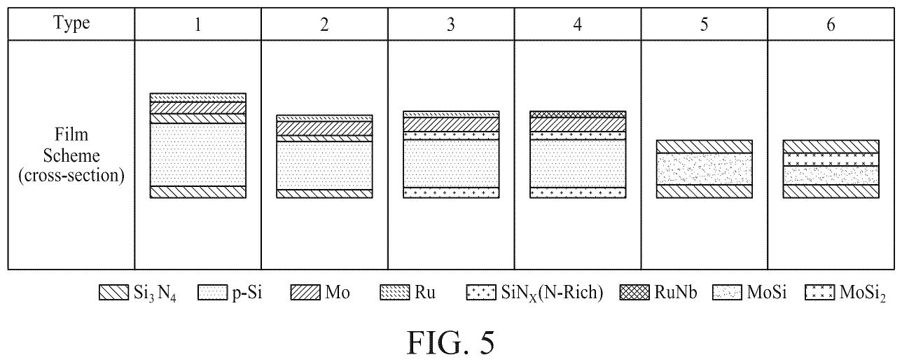

FIG. 5 illustrates a plurality of examples of pellicle membranes, such as the pellicle membrane 404, in accordance with some embodiments. Exemplary embodiments or exemplary stacks are titled Type in a first row of the table for ease of reference. Type-1 pellicle membrane is a five-layered structure including, from bottom to top, a first silicon nitride (Si₃N₄) layer, a polysilicon (p-Si) layer, a second silicon nitride layer, a molybdenum (Mo) layer, and a ruthenium (Ru) layer. The polysilicon layer is used as a core layer of the pellicle membrane. The first and second silicon nitride layers may be used to protect the core layer (i.e., the polysilicon layer). The molybdenum layer may support thermal stability, mechanical stability and chemical durability while having a high EUV transmittance of about 90% or more. According to some embodiments, the ruthenium layer has an advantage of achieving a desired light transmission property and thermal dissipation. In some embodiments, the first silicon nitride layer may also serve as an etch stop layer during fabrication of the pellicle membrane, and the second silicon nitride layer may also serve as a diffusion barrier layer between the molybdenum layer and the polysilicon layer.

The polysilicon layer may have a first thickness being a maximum thickness among the layers of the pellicle membrane. The first thickness is, for example, equal to or less than about 40 nm. The first silicon nitride layer may have a second thickness less than the first thickness. In an embodiment, the first silicon nitride layer may have a second thickness much less than the first thickness. Herein, the term “much less than” indicates smaller by at least ten times. According to some embodiments, the second silicon nitride layer has a third thickness less than the second thickness, the molybdenum layer has a fourth thickness between the first and second thicknesses, and the ruthenium layer has a fifth thickness less than the third thickness. Type-1 pellicle membrane may have an EUV transmittance of about 80-85%, and an EUV reflectivity of about 0.05%-0.08%.

Type-2 pellicle membrane includes the same stack structure as Type-1 pellicle membrane. The stack structure of Type-2 pellicle membrane may be thinner than that of Type-1 pellicle membrane. For example, in Type-2 pellicle membrane, the polysilicon layer of the Type-2 pellicle membrane has a thickness less than the first thickness of the polysilicon layer of the Type-1 pellicle membrane, and thereby increasing EUV transmittance (e.g., from about 83% to about 88%). Type-2 pellicle membrane may have an EUV reflectivity of about 0.03%-0.07%. Furthermore, in Type-2 pellicle membrane, the first silicon nitride layer, the second silicon nitride layers, and the ruthenium layer each have a thickness less than each of the respective second, third, and fifth thicknesses of Type-1 pellicle membrane. In addition, the molybdenum layer of Type-2 pellicle membrane has a thickness greater than the fourth thickness of Type-1 pellicle membrane.

Referring to Type-2 and Type-3 pellicle membranes, the first and second nitride layers are N-rich silicon nitride (SiNₓ) layers. The N-rich layers are used to increase mechanical stiffness of the pellicle membrane. In some embodiments, the first silicon nitride layer may have the second thickness, and the second silicon nitride layer may have the third thickness, both thicknesses being of Type-1 pellicle membrane. Type-3 pellicle membrane may have an EUV transmittance of about 83%-88%, and an EUV reflectivity of about 0.03%-0.07%.

Referring to Type-3 and Type-4 pellicle membranes, the ruthenium layer is replaced with a ruthenium niobium (RuNb) layer to meet the critical dimension (CD) requirement of pellicle membrane. Type-4 pellicle membrane may have an EUV transmittance of about 84%-88%, and an EUV reflectivity of about 0.03%-0.07%.

Type-5 pellicle membrane is a three-layered structure including, from bottom to top, a first silicon nitride layer, a molybdenum silicide (MoSi) layer, and a second silicon nitride layer. The molybdenum silicide layer is used as a core layer of the pellicle membrane, and the first and second silicon nitride layers are used to protect the molybdenum silicide layer. The molybdenum silicide layer has sixth thickness less than the first thickness of the polysilicon layer in Type-1 pellicle membrane, thereby increasing EUV transmittance (e.g., from about 86% to about 90%). In some embodiments, the sixth thickness is less than about one half of the first thickness. The first and second silicon nitride layers may have substantially equal thicknesses, which are slightly greater than that of the first silicon nitride layer in Type-1 pellicle membrane. Type-5 pellicle membrane may have an EUV reflectivity of about 0.02%-0.06%.

Type-6 pellicle membrane includes a four-layered structure. Compared to Type-5 pellicle membrane, Type-6 pellicle membrane further includes a molybdenum disilicide (MoSi₂) layer inserted between molybdenum silicide layer and the second silicon nitride layer and the molybdenum silicide (MoSi) layer has a reduced thickness compared to Type-5 pellicle membrane. The molybdenum disilicide (MoSi₂) layer may serve as a heat dissipating layer for improving the thermal dissipating effect so as to ensure the performance of the pellicle membrane. More particularly, the heat dissipation layer restrains temperature increase on the surface of the pellicle membrane during the exposure operation, and thus lowers temperature and improves thermal properties of the pellicle membrane. Type-6 pellicle membrane may have an EUV transmittance of about 86%-90%, and an EUV reflectivity of about 0.02%-0.06%.

Exemplary thicknesses of the stacks discussed above and illustrated in FIG. 5 include Type 1: Ru layer 2.0-3.0 nanometers (nm), Mo layer 3.5-4.5 nm, pSi 34-38nm, and/or SiN 3-3.5 nm; Type 2, Ru layer 1.5-2.5 nm, Mo layer 4.0-5.0 nm, pSi 27-32 nm, and/or SiN 2-2.5 nm; Type 3, Ru layer 1.7-2.5 nm, Mo layer 4.0-5 nm, pSi 26-33 nm, and/or SiN 2.5-3.5 nm; Type 4, Ru layer 1.5-3 nm, Mo layer 4.0-5.0 nm, pSi 27-31 nm, and/or SiN 2.5-3.5 nm; Type 5, MoSi 15-35 nm, and/or SiN 3.5-4.5 nm; Type 6, MoSi 13-18 nm, and/or SiN 3-4 nm (MoSi2 1:2, MoSi 1:1). These thicknesses are exemplary only and not limiting except to the extent specifically recited in the claims that follow.

As discussed above, the pellicle membrane is flexible and has a tendency to deform when exposed to pressure gradients, mechanical vibrations or mechanical stresses when in use or in transport. For example, when an amount of the particles attached to the pellicle membrane 404 increases, the pellicle membrane 404 may start to deform in a downward direction due to a weight of the particles. Sagging or deformation of the pellicle membrane 404 may also occur due to gravity. Sagging, and measurement thereof, is further discussed below. It is noted that the flexibility, and the sagging/deformation of the pellicle membrane is dependent upon the stack composition and thicknesses. Thus, the stack information such as provided by FIG. 5 is included in the database 316 available to the controller 314.

It is noted that during the exposure operation, which as an example is discussed in the context of FIG. 3, the electromagnetic radiation ER_1 provided by the radiation source 324 is guided through the illumination optical module 308 and the pellicle membrane 404, and reaches the reticle 402. The patterned electromagnetic radiation ER_2 reflected by the pattern passes through the pellicle membrane 404 and is guided to the substrate 320 through the projection optical module 310. The pellicle membrane 404 may absorb part of the energy of the electromagnetic radiation ER_1 and the patterned electromagnetic radiation ER_2. The absorbed energy may cause generation of heat energy on the pellicle membrane 404. As such, deformation or chemical changes on the material layers (e.g., oxidation) of the pellicle membrane 404 by thermal accumulation may occur. The pellicle membrane 404 may lose its elasticity or become brittle as heat-induced deformation occurs. Like the stack information, information as to the deformation or chemical changes of the material layers (e.g., developed by experimental or modeling) may also be provided in the database 316.

During the exposure operation, the movement of the reticle stage 304 affects the deformation of the pellicle membrane 404. More particularly, it may be desired for the reticle assembly 302 to be moved at high speed by the reticle stage 304 in order to achieve high throughput. Such high speed may introduce undesirable air flow across the pellicle membrane 404, thereby increasing the likelihood or extent of deformation of the pellicle membrane 404. If the deformation of the pellicle membrane 404 exceeds a tolerable level, the pellicle membrane 404 may break, leading to damage or contamination of an unprotected reticle or other elements of the exposure tool 202 such as the mirrors of the illumination optical module 308 and the projection optical module 310. That may result in significant manufacturing process downtime. Additionally, the acceleration of the reticle before and between scans (discussed below) affects the deformation of the pellicle membrane 404. In particular, the deformation of the pellicle membrane 404 may be impacted by the acceleration of the reticle stage 304 during the photolithography process including, e.g., the acceleration to and deceleration from the scanning speed maintained in the feature region of the reticle 402. Therefore, in some embodiments, the inspection tool 203 shown in FIG. 2 is configured to measure the deformation level of the pellicle membrane 404, as discussed below.

The detector 312 is, for example, arranged adjacent to the reticle assembly 302. The detector 312 is configured to detect the energy of the patterned electromagnetic radiation ER_2 and provide a detection result to the control unit 314. While FIG. 3 only illustrates one detector 312 adjacent to the pellicle membrane 404, any suitable number of detectors 312 can be included in the exposure tool 202 and positioned at any suitable location near the optical path of the patterned electromagnetic radiation ER_2. It is noted that the position of the detector 312 may be varied outside of the path of ER_2. Further, in some embodiments, the detector 312 may be omitted and the energy may be determined from other sources such as simulation, modeling, experimental results, calculation from other processes (e.g., resist development) and/or other suitable metrics.

During the exposure operation, the radiation source 324 is configured to generate the electromagnetic radiation ER_1 having a radiation energy per unit area (also referred to “energy of process,” “energy of power,” or Eop). The provided radiation energy is basically stable during the exposure operation, while the patterned electromagnetic radiation ER_2 has an exposure energy which is affected by its interactions with features including the pellicle membrane 404 and thus, is dependent upon the quality (e.g., reflectivity, deformation) of the pellicle membrane 404. More particularly, during EUV irradiation, the pellicle membrane 404 may absorb part of the energy of the electromagnetic radiation ER_1 and the patterned electromagnetic radiation ER_2. The absorbed energy causes residual heat to the pellicle membrane 404. A thin oxide film may be formed on a surface of silicon-based layer in the pellicle membrane 404 due to the influence of heat. When the reticle assembly 302 is used repeatedly, the oxide film may grow thicker along with the exposure operation. The oxide film causes a reduction in the transmittance of the pellicle membrane 404 and thus a reduction in the transmitted exposure energy.

During the exposure operation, the pattern of the reticle 402 is transferred onto the photoresist layer 322 by exposing portions of the photoresist layer 322 to the patterned electromagnetic radiation ER_1, making the exposed portions either soluble or non-soluble in a developing solution. The soluble portions are then removed, thereby forming a patterned photoresist layer on the substrate 320. The substrate 320 can be further processed through the patterned photoresist layer 322, thereby forming desired device features in or on the substrate 320. Hence, the accuracy of the patterned photoresist layer plays a key role in device performance. The photoresist layer 322 irradiated by the patterned electromagnetic radiation ER_2 with reduced exposure energy may form the patterned photoresist layer have patterns unable to meet a specification (e.g., linewidth, line spacing, sidewall angle, or the like). It is therefore desirable to maintain the exposure energy required to cause a stable chemical transformation in exposed regions of the photoresist layer 322, such that the patterned photoresist layer can be manufactured with a high degree of quality control in pattern shape accuracy and uniformity.

In some embodiments, the control unit 314 is further configured to control the radiation energy of the radiation source 324, in order to tune the exposure energy of the patterned electromagnetic radiation ER_2. For example, the control unit 314 may be configured to control the radiation energy on the basis of the detection result provided by the detector 312. The radiation energy (Eop) may be proportional to a supply power of the radiation source, and the control unit 314 may control the radiation energy by increasing or decreasing the supply power.

According to some embodiments, the radiation source 324 is configured to generate the electromagnetic radiation ER_1 having the radiation energy of an initial level. The initial level is determined according to characteristics of the photoresist layer 322, the pellicle membrane 404, the pattern of the reticle 402, and/or other suitable metrics and is suitable to provide for accurate pattern exposure onto the photoresist layer 322.

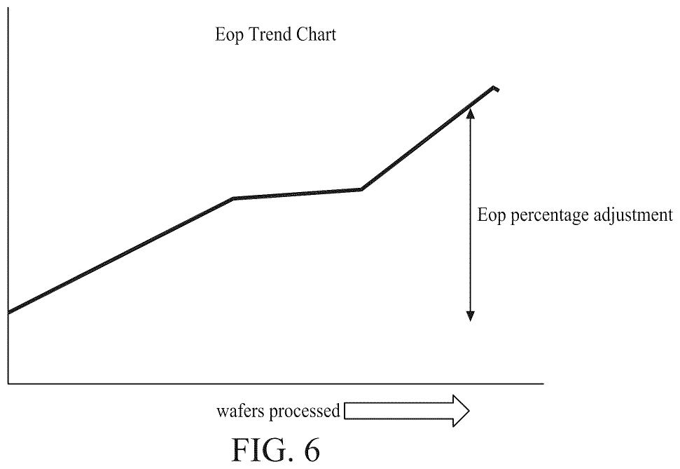

According an embodiment, in another exposure operation where the oxide film has been at least partially formed on the pellicle membrane 404 or the pellicle membrane 404 otherwise degraded, the radiation source 324 is configured to generate the electromagnetic radiation ER_1 having the radiation energy of an adjusted (increased) level. The adjusted level is determined according to the detection result provided by the detector 312 and/or determined based on input parameters of the reticle stack composition, the number of wafers run, pattern density or criticality, and/or other suitable inputs. The control unit 314 is further configured to determine an adjustment level in the radiation energy in response to this determination. The adjustment level may be a difference between the adjusted and initial levels. In some embodiments, the adjustment level is expressed in a percentage form in terms of the radiation and the exposure energy. FIG. 6 is illustrative is a graphical representation of the energy increasing as the wafer quantity processed increased. In an embodiment, the energy percentage adjustment is determined and, in some embodiments, the controller 314 determines after a certain threshold in Eop percentage adjustment (e.g., 5%-5.5%), the pellicle 404 is determined to need replacement. The energy adjustment percentage, Eop, is one of the pellicle quality indices used to determine a scan speed plan including acceleration profile management. For example, increasing percentages describing increasing risk to the pellicle as discussed above.

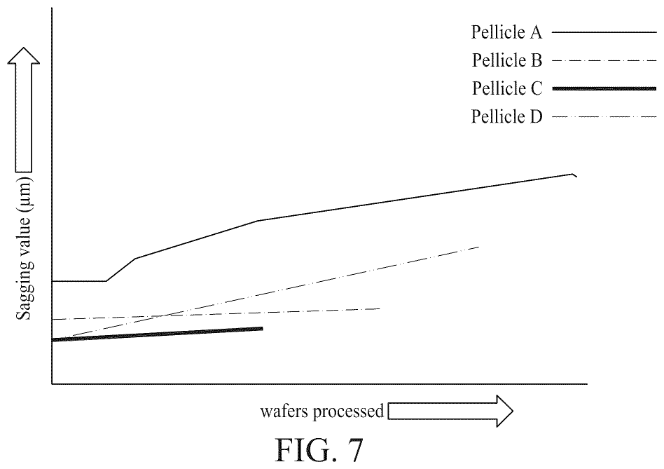

In addition to the controller 314 and database 316 gathering percentage adjustment for the energy, as discussed above, other pellicle indices are also stored and/or gathered by the controller 314 and database 316 indicative of the pellicle quality and lifespan. The database 316 may contain information about a usage history of the reticle 402, a composition of the pellicle membrane 404, a usage history of the pellicle membrane 404, a deformation level of the pellicle membrane 404 provided by an external inspection tool (e.g., apparatus 203), etc, which are all pellicle indices indicative of and useful to determining the pellicle quality. FIG. 7 is illustrative of a trend chart illustrating deformation or sagging measurements in microns (e.g., sag value) provided by an inspection tool of various reticle assemblies 302 and pellicle membranes 404. In an embodiment, the controller 314 obtains the deformation measurement to determine whether the pellicle 404 needs replacement and/or determine pellicle quality indices used to determine a scan speed plan including acceleration profile management.

In some embodiments, the control unit 314 is configured to determine a risk level based upon one or more of the indices received including those discussed above. In an embodiment, the risk level of the pellicle membrane 404 is determined based on the deformation level of the pellicle membrane 404 (e.g., sag value). Further considerations include the movement speed of the reticle stage 304 (e.g., scan speed plan) previously performed and subsequently planned. Another consideration may be an adjustment level in the radiation energy such as illustrated in FIG. 6. Another consideration can be pellicle indices such as the composition of the pellicle membrane 404. One or more of these factors (pellicle indices) may be used to assign a risk level. And the risk level may correspond to action suitable for the pellicle such as requiring replacement, continuing use at a standard scan speed and acceleration profile or continuing use under a modified scan speed and acceleration profile (e.g., decreasing the acceleration rate). The control unit 314 is capable of controlling the scanning speed and the acceleration of the reticle stage 220 based on the risk level associated with the pellicle membrane 404.

As indicated above, the control unit 314 may receive deformation information (e.g., sag value) from the inspection apparatus 203. That is, in an embodiment, the reticle assembly 302 is provided to the inspection apparatus 203, which measures a deformation or sagging of the pellicle membrane 404. This measurement may be delivered to the controller 314 and/or stored in the database 316. In an embodiment, the reticle assembly 302 is provided to the inspection apparatus 203 using the handler 204 at various intervals of the production of wafers using the reticle 402 of the reticle assembly 302. For example, procedures may be established to perform measurement after a given number of wafers are exposed.

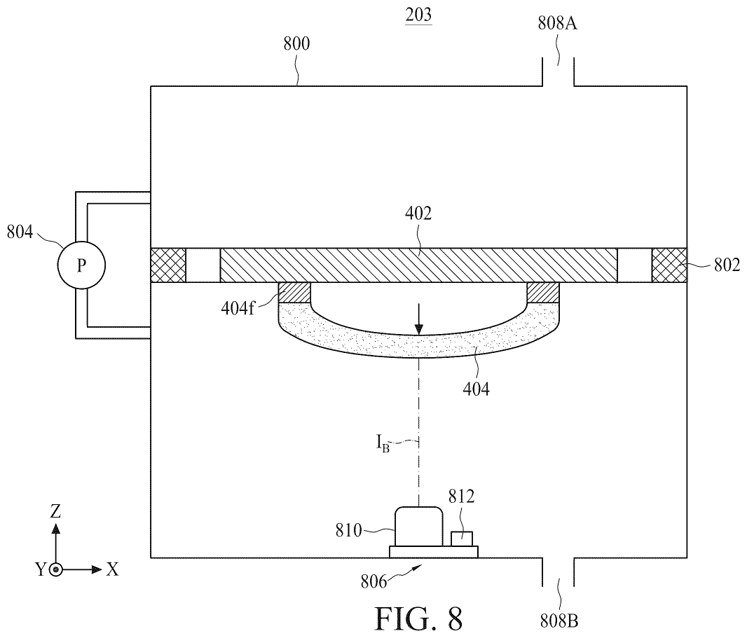

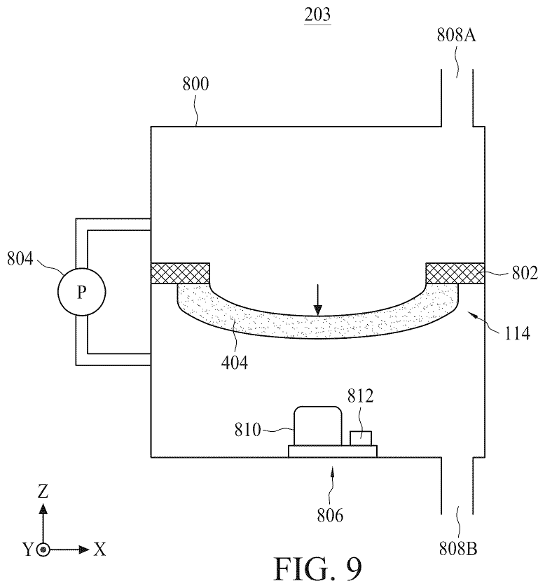

FIGS. 8 and 9 are illustrative of a cross-sectional diagrammatic view of embodiments of a deformation measurement apparatus such as the inspection apparatus 203. FIG. 8 is illustrative of an embodiment that performs a deformation measurement of the pellicle while positioned on the reticle; FIG. 9 is illustrative of an embodiment that performs a deformation measurement of the pellicle while detached from the reticle. Referring to FIGS. 8 and 9, the inspection tool 203 includes an inspection chamber 800, a retaining structure 802, a pressure gauge 804, and an inspection unit 806. The inspection chamber 800 includes a gas inlet 808A through which a supply gas is received, and a gas outlet 808B that expels the supply gas of the inspection chamber 800. The supply gas is, for example, an extreme clean dry air (XCDA) gas. The XCDA gas may be beneficial in reducing humidity in the inspection chamber 800.

The retaining structure 802 may extend from an internal wall of the inspection chamber 800 and may be used to hold the pellicle 404 to be inspected. In some embodiments, when the pellicle 114 or the reticle assembly 302 is attached to the retaining structure 802, the inspection chamber 800 is separated by the pellicle 404 or the reticle assembly 302 and includes an upper space and a lower space. The upper and lower spaces are air-tight spaces. A pressure difference between the upper and lower spaces may cause the pellicle membrane 404 to become distorted, wrinkled, broken, or otherwise damaged. In some embodiments, the pressure gauge 804 monitors the pressures of the upper and lower spaces of the inspection chamber 800. In some embodiments, the pressure of the inspection chamber 800 is adjusted by a pump (not shown) coupled to the gas outlet 808B. The pressure gauge 804 and the pump are utilized to equalizing the pressures of the upper and lower spaces.

In some embodiments, the inspection of the pellicle membrane 404 is carried out by directing an inspection (light) beam to the pellicle membrane 404 in a darkroom and visually detecting light scattered from the deformation region and/or the contaminants. In some embodiments, the inspection unit 806 includes an optical emitter 810 and one or more optical detectors 812. The optical emitter 810 generates an inspection beam I_{B} and projects the inspection beam I_{B} to the pellicle membrane 404. In some embodiments, the inspection beam I_{B} has a beam size with its projection area smaller than an area of the pellicle membrane 404. For example, the optical emitter 810 includes a laser diode to project a laser beam with a relatively small projection area onto the pellicle membrane 404. The inspection beam I_{B} has a wavelength range, and the pellicle membrane 404 can be transparent in such wavelength range.

The optical detector 812 collects scattered light after the inspection beam I_{B} interacts with the pellicle membrane 404. In some embodiments, the optical detector 812 detects the scattered beams from the illuminated pellicle membrane 404 or the substances such as particles present on the pellicle membrane 404. In the inspection tool 203 illustrated in FIG. 8, the optical detector 812 further collects the reflected beam from the reticle 402. The inspection unit 806 may generate an inspection result in accordance with the scattered light. The optical detector 812 may include, but is not to be limited to, a complementary metal oxide semiconductor (CMOS) sensor or a charge-coupled device (CCD).

The inspection unit 806 may perform the inspection in one or more regions of the pellicle membrane 404 and generates an inspection result (e.g., sagging value) indicative of the deformation level of the pellicle membrane 404 based on the detected scattered light. The control unit 314 may receive the inspection result and be configured to determine the risk level of rupture of the pellicle membrane 404 according to the inspection result.

The deformation level of the pellicle membrane 404 (see arrow) may progressively increase as the pellicle 404 undergoes repeated use (for example through repeated exposure operations). A greater degree of deformation of the pellicle membrane 404 may result in a greater amount of the scattered beam detected by the optical detector 812.

Thus, the control unit 314 may be configured to gather information from several sources including the database 316, the inspection apparatus 203, and the lithography tool 202. From the gathered information, referred to herein as the pellicle quality indices—(e.g., Eop adjustment, sagging value, pellicle stack composition, original or previous state of pellicle, wafers exposed), is used to determine several, as but one example, three, risk levels according to conditions of the deformation level of the pellicle membrane 404 and the adjustment level of the radiation energy, details of which are discussed below.

In one example, in response to the pellicle membrane 404 found to include the deformation level being less than about 10 μm and the adjustment level of the radiation energy (e.g., Eop percentage adjustment) found being less than about 3%, the control unit 314 is configured to determine that the pellicle membrane 404 is at a low risk level of rupture during the exposure operation. In some embodiments, the pellicle membrane 404 at the low risk level of rupture can be used in subsequent exposure operations with about 1,000 pieces to about 10,000 pieces of the substrate or wafer. The control unit 314 may be configured to move the reticle stage 304 using a standard scan speed profile. In an embodiment, the control 314 may implement a uniform speed when the pellicle membrane 404 is determined to be at the low risk level of rupture.

In another example, in response to the pellicle membrane 404 found to include the deformation level ranging between about 10 μm and about 20 μm and the adjustment level in the radiation energy (e.g., Eop percentage adjustment) ranging between about 3% and about 4.5%, the control unit 314 is configured to determine that the pellicle membrane 404 is at a medium risk of rupture during the exposure operation. In some embodiments, the pellicle membrane 404 at the medium risk level of rupture can be used in subsequent exposure operations with about 500 pieces to about 5,000 pieces of the substrate. The control unit 314 may be configured to move the reticle stage 304 using a standard scan speed profile. In an embodiment, the control 314 may implement a uniform speed when the pellicle membrane 404 is determined to be at the medium risk level of rupture. In an embodiment, small adjustments to the acceleration profile (e.g., decreases) may be made.

In yet another example, in response to the pellicle membrane 404 found to include the deformation level ranging between about 20 μm and about 30 μm and the adjustment level in the radiation energy (e.g., Eop percentage adjustment) being greater than about 4.5%, the control unit 314 is configured to determine that the pellicle membrane 404 is at a high risk level of rupture during the exposure operation. In some embodiments, the pellicle membrane 404 at the high risk level of rupture can be used in subsequent exposure operations with about 100 pieces to about 1,000 pieces of the substrate. The control unit 314 may be configured to move the reticle stage 304 using a reduced scan speed profile including a reduced acceleration management. In an embodiment, the control unit 314 may be configured to move the reticle stage 304 using a non-uniform speed when the pellicle membrane 404 is determined to be at the high risk level to rupture. In an embodiment, greater adjustments to the acceleration profile (e.g., decreases) may be made. The control unit 314 may provide an alarm or other indicator of the risk level of the pellicle.

In some embodiments, the control unit 314 can be configured to alert on-site technicians for replacing the pellicle 404 with a new, qualified pellicle in response to the adjustment level of the radiation energy (e.g., Eop percentage adjustment) greater than a tolerable level (e.g., 5% or 5.5%). The control unit 314 may be configured to notify the on-site technicians of the risk level of rupture (e.g., low, medium, high).

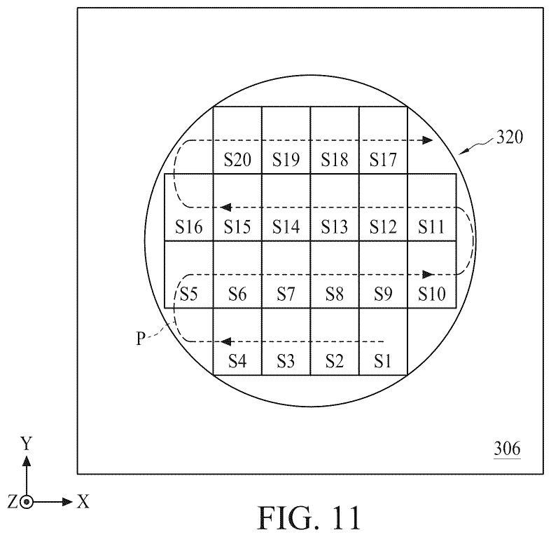

FIG. 11 is a plan view of the substrate 320, which is held by the substrate stage 306 in accordance with some embodiments of the present disclosure. As shown in FIG. 11, a plurality of shot regions S1 to S20 each having a predetermined size are defined on the substrate 320. The shot regions S1 to S20 are, for example, arranged in a grid on the substrate 320. Each of the shot regions S1 to S20 may include one or more die regions (not shown) in which an integrated circuit will manufactured. The dashed line labeled P illustrates a processing sequence for transferring of the pattern on the reticle 112 to the shot regions S1 to S20.

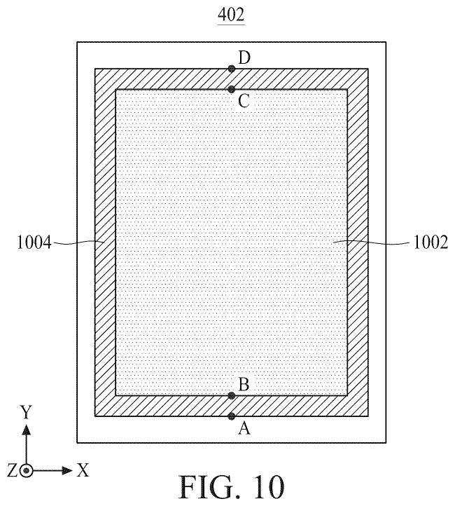

FIG. 10 schematically illustrates a top view of the reticle 402 in accordance with some embodiments of the present disclosure. The reticle 402 includes a feature region 1002 and a border region 1004 formed at an edge of the feature region 1002. The pattern of the reticle 402 (e.g., the pattern 302P shown in FIGS. 3, 4A) is formed in the feature region 1002. In addition, the border region 1004 is utilized to avoid over-exposure from the edges of the reticle 402 onto the adjacent edges of two adjacent shot regions to be defined on the substrate 320 (see, e.g., S1 to S20 of FIG. 11 along exposure plan P). The portion of the electromagnetic radiation ER_1 projected onto the border region 1004 would be absorbed accordingly. For example, referring to FIG. 11, when a shot region S8 is irradiated, the pattern in the feature region 1002 of the reticle 402 is transferred to the shot region S8, and the border region 1004 is utilized to at least prevent irradiation onto the edges of the adjacent shot regions S2, S7, S9, and S14.

The scanning speed profile, which includes a steady state scan speed and an acceleration profile, of the reticle stage 304 influences the deformation of the pellicle membrane 404 as discussed above. Therefore, the deformation level of the pellicle membrane 404 is monitored during the exposure operation(s). If the deformation level of the pellicle membrane 404 provided by the inspection tool 203 exceeds a predetermined first threshold, the control unit 314 may determine that the pellicle membrane 404 is susceptible to rupture during subsequent exposure operations. If the pellicle membrane 404 ruptures or is otherwise damaged during an exposure operation, the reticle 402 will no longer be protected and may be scratched or otherwise damaged by the broken pellicle membrane 404 itself. In addition, a rupture of pellicle membrane 404 may break into pieces, and the debris of the broken pieces of the pellicle membrane 404 may contaminate the surrounding environment. And this risks contamination of the exposure tool 202. Due to the risk, the methods and systems discussed herein provide for addressing the risk by an acceleration management plan and/or removal and replacement of the pellicle.

On the other hand, if the deformation level of the pellicle membrane 404 provided by the inspection tool 203 remains below a predetermined second threshold (wherein the predetermined second threshold is less than the predetermined first threshold), the control unit 314 may determine that the pellicle membrane 404 is not deformed or is deformed only slightly from its original position, and the optical, thermal, and mechanical properties of the pellicle membrane 404 are not adversely affected to the point of requiring replacement. This is also discussed above with reference to the assigned risk levels. As discussed, the pellicle membrane 404 having the deformation level less than the predetermined second threshold may be determined to be at the low risk of rupture. Furthermore, if the deformation level of the pellicle membrane 404 provided by the inspection tool 203 is between the predetermined first and second thresholds, the control unit 314 may determine that the pellicle membrane 404 to be at the medium risk of rupture. Depending on the risk level, an acceleration management plan may be put into place. In some embodiments, the deformation inspection of the pellicle membrane 404 may be performed before the exposure operation.

FIG. 12A illustrates a cross-sectional view of an electrostatic chuck 1200 for holding a reticle such as electrostatic chuck 304e of the reticle stage 304 discussed above. FIG. 12B illustrates a schematic view of the electrostatic chuck 1200 in accordance with some embodiments, FIGS. 12C and 12D illustrate cross-sectional views of the electrostatic chuck 1200 and the reticle 402 in accordance with some embodiments. Referring to FIGS. 12C and 12D, the electrostatic chuck 1200 may include a holder 1202 and a plurality of electrodes 1204a to 1204d. The holder 1202 may substantially seal the electrodes 1204a to 1204d from external contaminants such as moisture and chemicals. In some embodiments, the holder 1202 is made of an insulating material.

The electrostatic chuck 1200 may operate in a bipolar arrangement. For example, in FIG. 12C, a first voltage is applied to the electrodes 1204a and 1204b and causes electrostatic charges, e.g., positive charges, to accumulate near the electrodes 1204a and 1204b. Electrostatic charges of an opposite polarity, e.g., negative charges, accumulate on a left side of the reticle 402. In addition, a second voltage is applied to the electrodes 1204c and 1204d and causes negative charges to accumulate near the electrodes 1204c and 1204d. Electrostatic charges of the opposite polarity, i.e., positive charges, accumulate on a right side the reticle 402. Hence, a force F is generated by electrostatic attraction between the accumulated charges with opposite polarities, in which the force F holds or secures the reticle assembly 302 on the reticle stage 304. The force F may be a Coulomb force.

In an embodiment, the holder 1202 may be an imperfect insulator. Hence, over a period of time, an unwanted electrostatic charge may accumulate within the holder 1202. If a significant level of unwanted electrostatic charge accumulates within the holder 1202, an attraction force may be applied to the reticle assembly 302 even after the voltages supplied to the electrodes 1204a to 1204d are turned off. Because the attraction force is generated, a position of the reticle 402 may be changed when the reticle 402 is released from the reticle stage 304, or the reticle 402 may be damaged by a force applied to the reticle 402 during its release. The unwanted electrostatic charges accumulated on the holder 1202 may be removed by periodically reversing the polarity of the electrodes 1204a to 1204d. This can be done by switching polarities of the voltages that are applied to the electrodes 1204a to 1204d. As the polarities of the voltages applied to the electrodes 1204a to 1204d are switched, negative charges accumulate near the electrodes 1204a and 1204b and positive charges accumulate near the electrodes 1204c and 1204d, as shown in FIG. 12D. The positive and negative charges near the electrodes 1204a to 1204d may neutralize or deplete the unwanted electrostatic charges on the holder 1202. In some embodiments, the reticle 402 is released from the electrostatic chuck when the polarization is reversed.

The inspection of the pellicle membrane 404 such as the sag value may be performed when the polarization of the electrostatic chuck 1200 is reversed, i.e., the polarity switch period. After the inspection operation (e.g., deformation test determining a sag value), the inspection tool 203 is configured to provide real-time inspection results of the status of the pellicle membrane 404 to the control unit 314 for updating the operation parameters of the exposure tool 202. Performing the deformation measuring during the polarity switch period results in time savings.

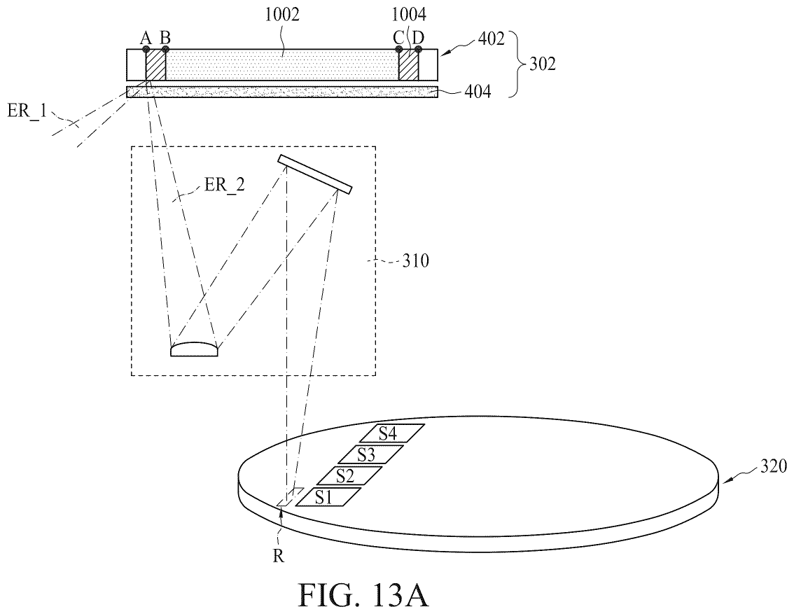

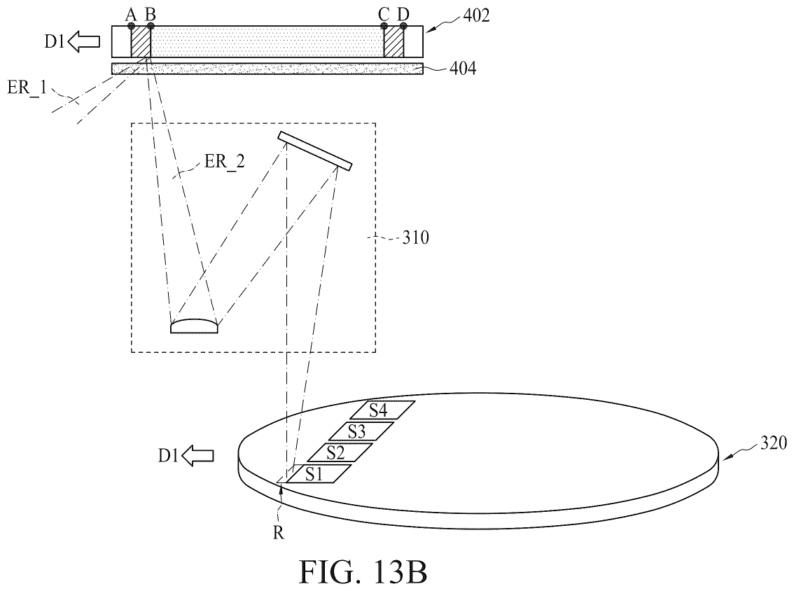

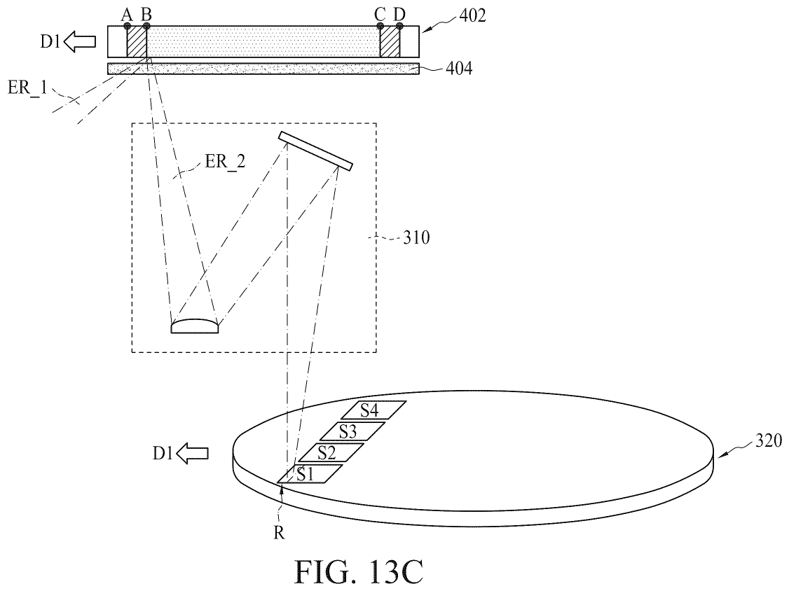

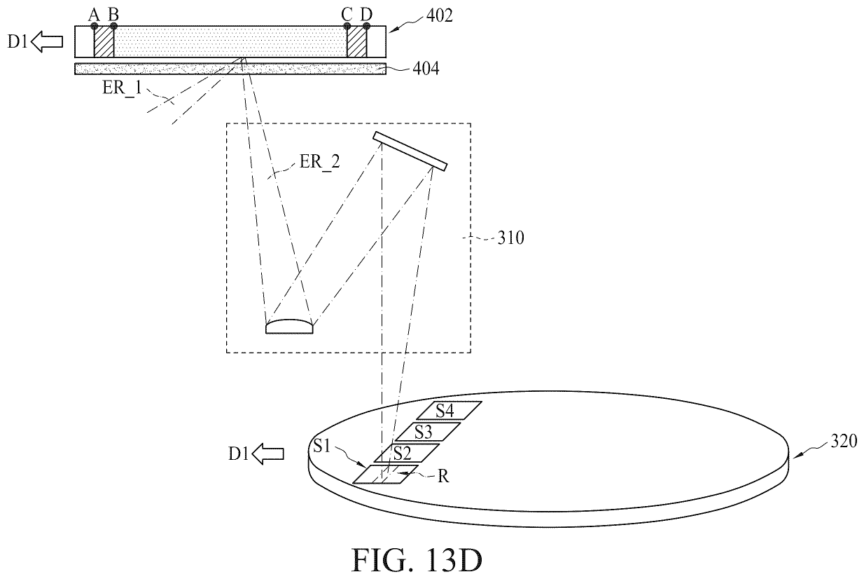

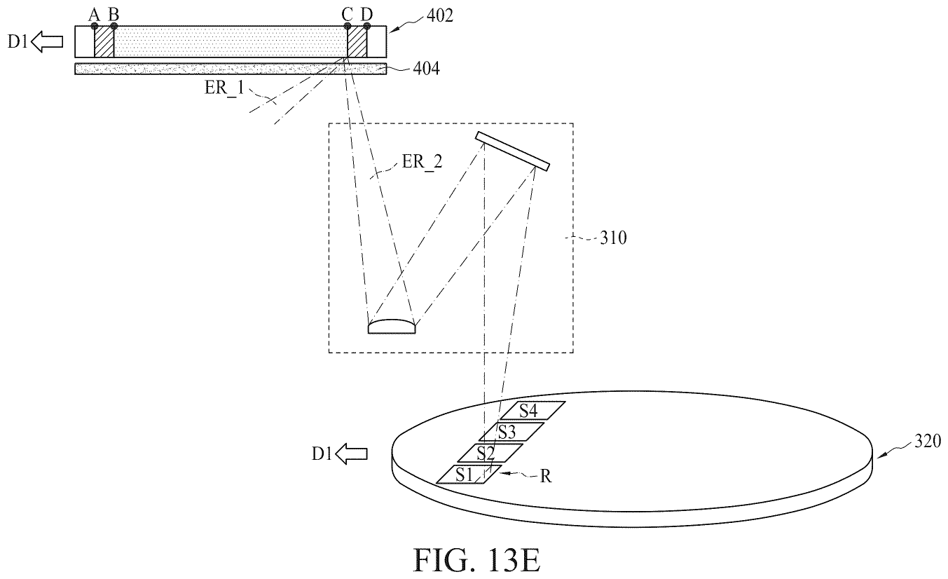

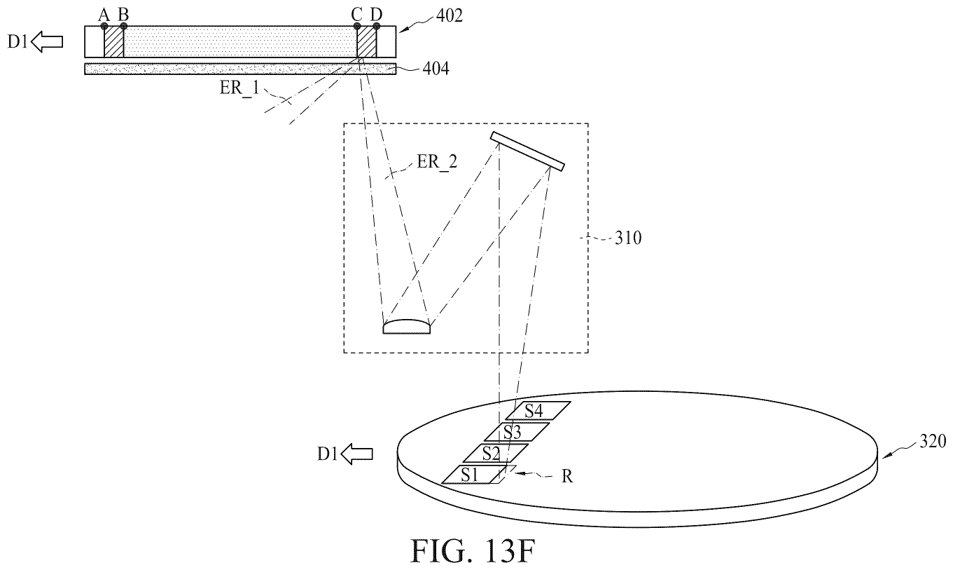

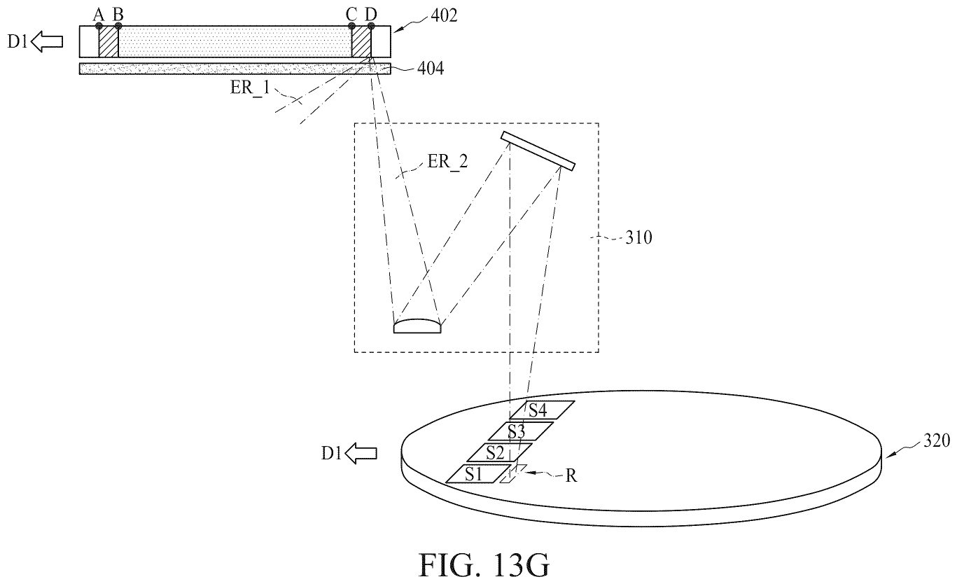

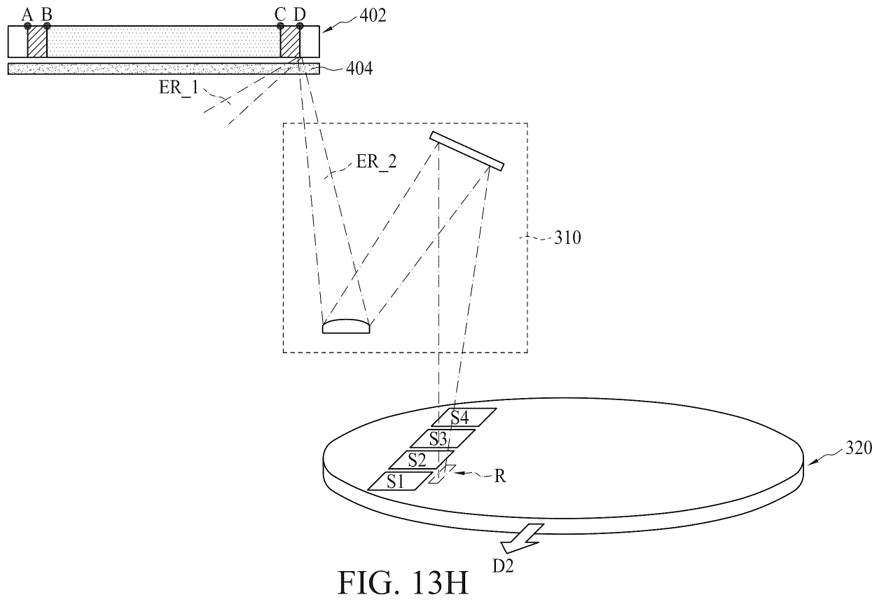

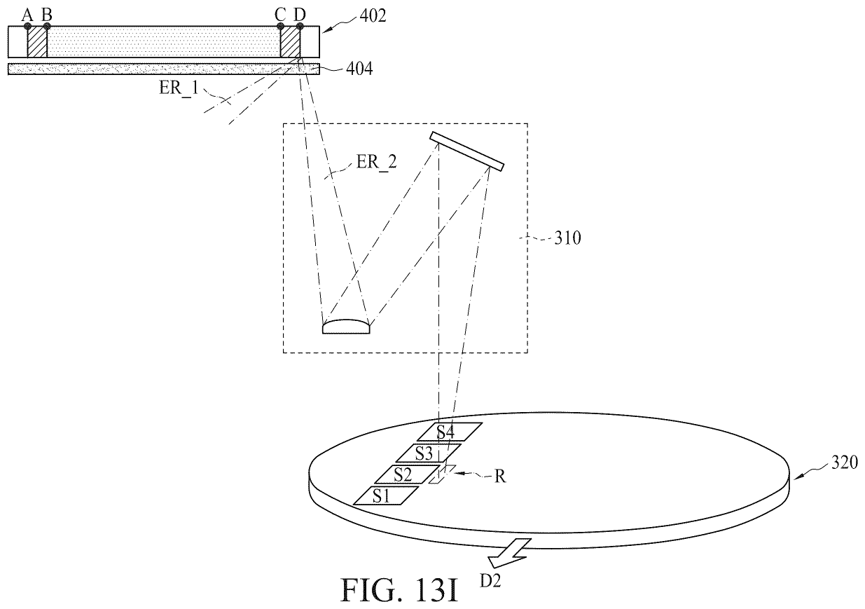

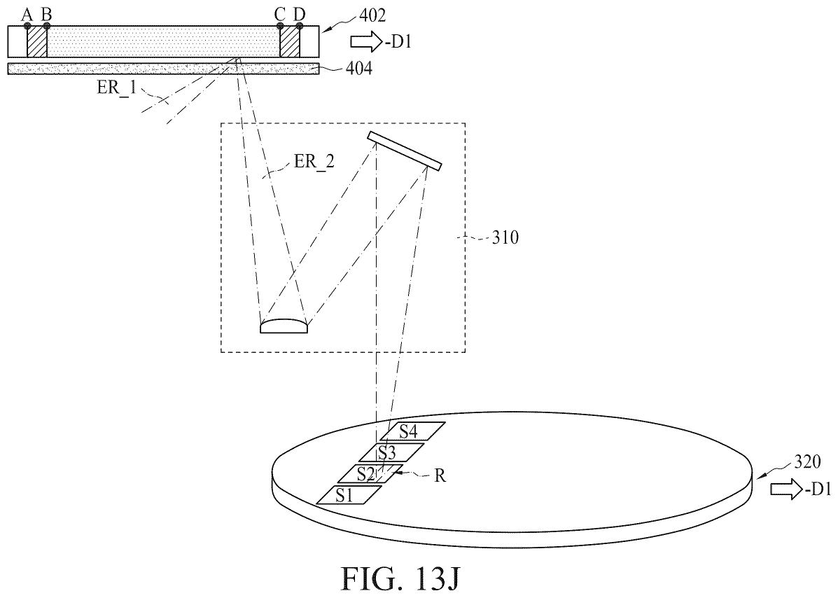

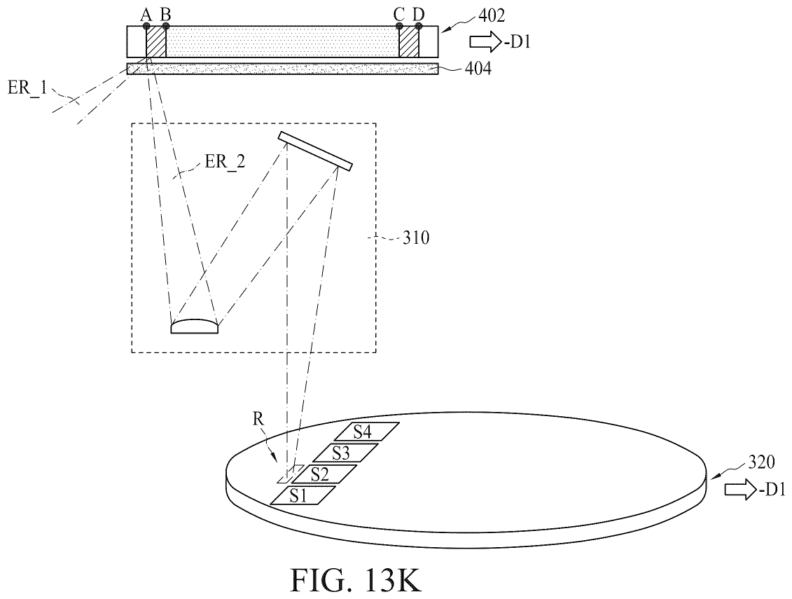

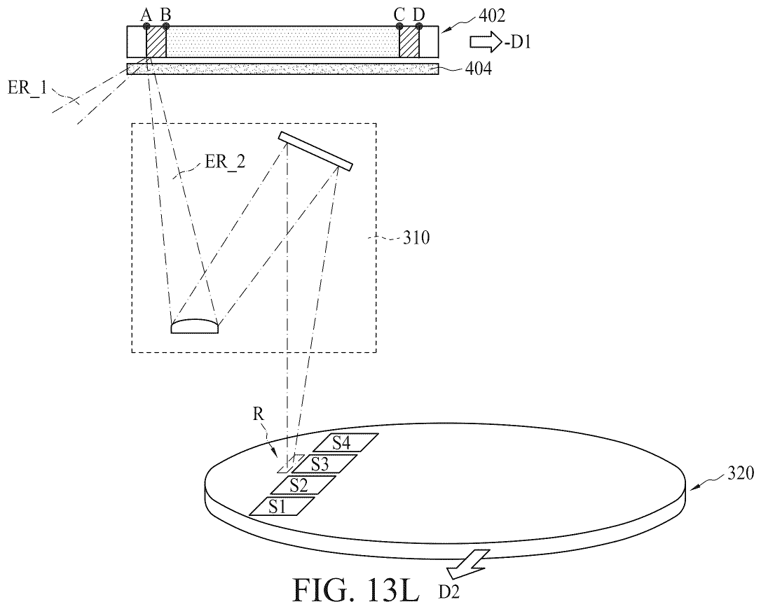

FIGS. 13A-13L schematically depict scanning and stepping operations performed on two adjacent shot regions in accordance with some embodiments of the present disclosure. During the exposure operation, the electromagnetic radiation ER illuminates a portion of the reticle 402. The border region 1004 (and the feature region 1002) in the illuminated portion pattern the electromagnetic radiation ER_1 and forms the patterned electromagnetic radiation ER_2. The patterned electromagnetic radiation ER_2 is directed onto the substrate 320 through the projection optical module 310 and defines an exposure region R on the substrate 320.

In some embodiments, the projection optical module defines the exposure region R whose area is reduced by two times or more compared to an area of the patterned electromagnetic radiation ER_1 at the reticle assembly 302. Alternatively, the projection optical module can be designed to define the exposure region R whose area is greater than or equal to the area of the patterned electromagnetic radiation ER_2 at the reticle 112. In some embodiments, the exposure region R has a rectangular shape, and the exposure region R can have a length substantially equal to a width of each shot area S1 to S20.

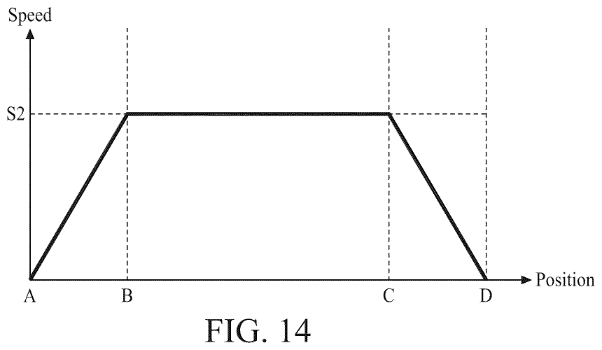

In FIG. 13A, the reticle 402 and the substrate 320 are synchronously moved in DI with an increasing acceleration. The scan is from point A to point B of the border region 1004. FIG. 14 is illustrative of the acceleration (i.e., scan acceleration speed). It is noted that the increasing speed or acceleration rate may be determined by the controller, such as controller 314, based on the input of the pellicle quality indices and/or deformation/sagging test as discussed above. In other words, FIG. 14 is provided by the acceleration management plan.

FIGS. 13B-13E, the reticle 402 pattern region 1002 is scanned at a constant speed, as illustrated by region B-C of FIG. 14. In particular, the pattern of the reticle 402 may be transferred to the shot region SI by synchronously moving the reticle 402 and the substrate 320 relative to the projection optical module 310. In some embodiments, the reticle stage 304 and the substrate stage 306 are synchronously moved in a first direction D1. In an embodiment, the scan speed may be determined by the controller 314.

In FIGS. 13F-13G, the reticle 402 and the substrate 320 are synchronously moved in direction D1 with a decreasing speed. The scan is from point C to point D of the border region 1004. FIG. 14 is illustrative of the deceleration (i.e., scan speed reduction). It is noted that the decrease of rate may be determined by the controller, such as controller 314, based on the input of the pellicle quality indices and/or deformation/sagging test as discussed above. In other words, FIG. 14 is provided by the acceleration management plan.

After the first scanning operation, a first stepping operation is performed. Referring to FIGS. 13H and 13I, during the first stepping operation, the reticle stage 304 remains stationary while the substrate stage 306 moves the substrate 320 in a second direction D2 until the next shot area to be exposed (e.g., the shot area S2) is aligned with the exposure region R. The second direction D2 is, for example, the X-direction.

Subsequently, a second scanning operation is performed to scan the shot region S2. Referring to FIGS. 131-13K, during the second scanning operation, the reticle stage 304 moves the reticle 402 and the substrate stage 306 moves the substrate 320 in a reversed first direction-D1, so that the shot region S2 is scanned from the right side of the shot region S2 to the left side of the shot region S2. Again, the exposure process is performed according to a scan speed profile including an acceleration management (i.e., the increase/decrease of speed during the edge regions of the scan). When the second scanning operation for the shot region S2 has been completed, a second stepping operation is performed between the shot regions S2 and S3. During the second stepping operation between the shot regions S2 and S3, the substrate stage 230 moves the substrate 320 in the second direction D2 to align the shot region S3 with the exposure region R, as shown in FIG. 13L. It is noted that the speed profile corresponding to the second scanning operation is also reflected by FIG. 14 and may be provided by the controller 314 acceleration management plan.

As the exposure operation progresses, the pattern defined on the reticle 402 is sequentially transferred to each shot region S1 to S20 of the substrate 320 by repeating the scanning operation and the stepping operation. In some embodiments, during the exposure operation, the odd-numbered shot regions (e.g., S1, S3, S5, etc.) are scanned from left sides to right sides thereof, and the even-numbered shot regions (e.g., S2, S4, S6, etc.) are scanned from right sides to left sides thereof. In alternative embodiments, all of the shot regions S1 to S20 may be scanned in a same direction (e.g., the first direction). In such embodiments, during the stepping operation, the reticle stage 304 moves the reticle 402 in the first reversed direction −D1. In the meanwhile, the substrate stage 306 moves the substrate 320 in the second direction D2 as well as the first reversed direction −D1 to align the shot region to be exposed with the exposure region R. Compared to the exposure operation in which all of the shot areas S1 to S20 are scanned in the same direction, the exposure operation in which the even-numbered shot areas S1 to S20 are scanned in the first direction D1 and the odd-numbered shot areas S1 to S20 are scanned in the first reversed direction −D1 may reduce a stepping distance of the exposure region R while completing the exposure task of all shot areas S1 to S20. The scanning speed, and the acceleration and deceleration during the scanning of the border region 1004 is provided by the controller 314 according to the acceleration management plan based on the pellicle 404 risk.

FIG. 15 provides a schematic view of a system 1500 that may be substantially similar to that illustrated in FIG. 2 and includes a designation of the surrounding environments. In an embodiment, a load port is provided in an atmosphere region (e.g., cleanroom) for receiving reticle assemblies. In an embodiment, the load port receives reticle pods such as illustrated in FIG. 4B. A handler or robot is used to retrieve the reticle assemblies and provide them to a load lock region. Within the load lock region, a transition to a vacuum atmosphere is provided. A second handler or robot is used to retrieve the reticles and deliver to various processes and features including a bar code reader (2D BC reader), EUV inner pod (EIP Library) storage, cover/replace/removal feature, a reticle stage such as discussed with reference to FIG. 3, a deformation/sag measurement tool such as illustrated by measurement 203 and as exemplified by reference to FIGS. 8-9.

FIG. 15 illustrates that the lithography system 1500 may include an additional chamber holding the deformation measurement (e.g., the deformation/sag measurement tool). In an embodiment, a vacuum environment is not broken, e.g., maintained, between the tools such as the deformation measurement and the reticle stage. In other embodiments, the deformation/sag measurement tool is positioned outside of the system (e.g., outside of the vacuum chamber including the reticle stage for EUV processes. Since the inspection tool is arranged within the lithography system, reduced delivery time may be achieved. The inspection tool may also be configured to provide dynamic feedback measurement results to acceleration controller such as controller 314 and thus, to the reticle stage within the system of FIG. 15.

In an embodiment, the reticle assembly received at the load port of the system of FIG. 15 is provided in an inner pod (EIP) with a surrounding outer pod (EOP) that encases the EIP. The pods may be substantially similar as discussed above with reference to FIG. 4B. In an embodiment, the outer pod is opened in atmosphere to retrieve the inner pod, which is provided to the load lock. The inner pod is then moved from the load lock chamber to the EIP library where it stored prior to use. A bar code reader (2D BC reader) may read a barcode on the reticle for example through a window of the inner pod prior to or after the storage. In an embodiment, the inner pod is removed prior to providing the reticle to the reticle stage.

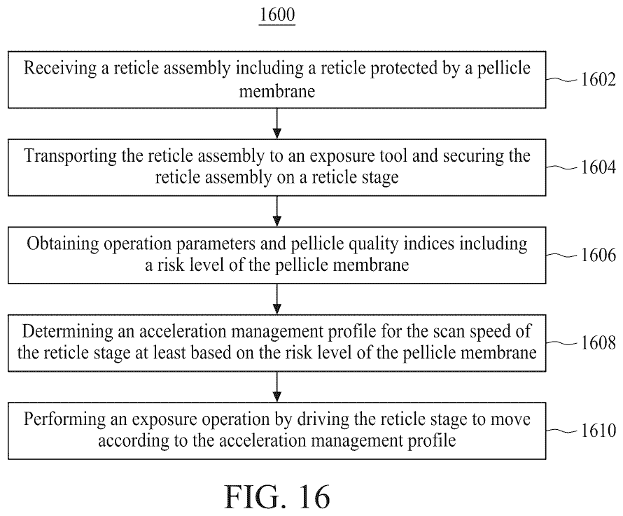

FIG. 16 is another flowchart showing a method 1600 according to aspects of one or more embodiments of the present disclosure. The method 1600 may be a continuation of the method illustrated in FIG. 1. The method 1600 includes a block 1602 of receiving a reticle assembly, wherein the reticle assembly includes a reticle protected by a pellicle membrane. In an embodiment, the reticle assembly is provided in a reticle pod. The method 1600 further includes step 1604 of transporting the reticle assembly to an exposure tool and securing the reticle assembly on a reticle stage. In a block 1606, the method includes obtaining parameters including a risk level of the pellicle membrane. In a block 1608, a scan speed profile including an acceleration management plan for the scan speed for the reticle stage is determined at least partly based on the risk level of the pellicle membrane. And in a block 1610, the method includes performing an exposure operation by driving the reticle stage according to the scan speed profile with acceleration management. In an embodiment, the acceleration management and scan speed is developed as discussed above by acquiring pellicle quality indices including but not limited the pellicle stack configuration, the power measurement (Eop) adjustment, the wafer count, and receiving the deformation or sagging measurement for the pellicle. These inputs are used to generate a risk level of the pellicle membrane in block 1606, which in turn in block 1608 is used to determine a scan speed profile including where a greater acceleration/deceleration rate is provided for a high quality membrane and a lower acceleration/deceleration rate is provided for a lower quality membrane. In an embodiment, the inputs provided in block 1606 instruct that blocks 1608 and 1610 of the method 1600 be omitted and the pellicle be replaced.

The method 1600 is described for a purpose of illustrating concepts of the present disclosure and is not intended to limit the present disclosure. Additional operations can be provided before, during, and after the method described above, and some operations described in the method 1600 can be replaced, eliminated, or moved around for additional embodiments of the method 1600.

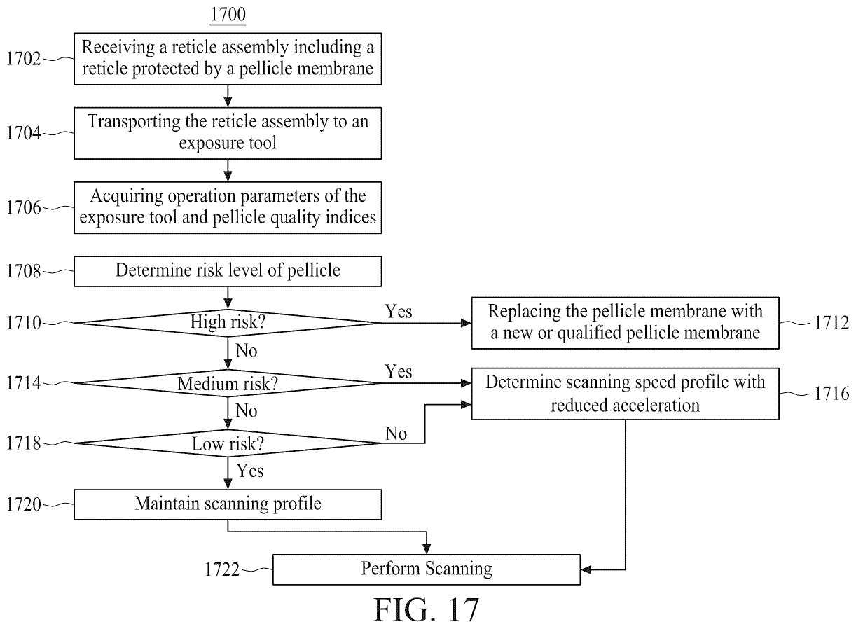

FIG. 17 is illustrative of a method 1700, the following describes the method 1700, and aspects of the method 1600 and method 100, using the above-mentioned photolithography apparatus 200 as an example. The method 1700 begins at block 1702, in which a reticle assembly such as reticle assembly 302 is received. The reticle assembly 302 includes a reticle 402 having a pattern 302P to be transferred to a material layer (e.g. photoresist 322) of a substrate (e.g., wafer 320). The pattern of the reticle 302P is protected from contamination by a pellicle membrane 404 of the reticle assembly.

The method 1700 continues with the block 1704, in which the reticle assembly 302 is transported to a tool, which may be substantially similar to FIGS. 2 and/or 15 providing an exposure tool having a reticle stage. In an embodiment, block 1704 is performed while the reticle assembly is contained in a pod structure such as discussed above.

The method 1700 then continues to block 1706 and block 1708 where operation parameters of the exposure tool and pellicle quality indices are gathered. The operation parameters may include state indices acquired include one or more of energy of power (EOP) status, wafer movement (W.M.) status, pellicle type (e.g., membrane film scheme details), original state of the membrane film (e.g., deformation), baseline scan speed profile and/or other suitable parameters. The baseline scan speed profile may include a scan speed (e.g., a uniform speed for scanning the feature region 1002) and an acceleration profile (e.g., rate and pulse shape). That is, in some embodiments, the scanning speed profile includes a plurality of sections. The sections of the scanning speed profile may be corresponding to the feature region 1002 and the border region 1004 of the reticle 402. In some embodiments, the scanning speed profile includes three sections, i.e., an initial section (e.g., acceleration), a scanning section and a final section (e.g., deceleration). In some embodiments, the initial section, the scanning section and the final section are identified according to the boundaries of the feature region 1002 and the border region 1004. In an embodiment, the scan speed is a first speed. In a further embodiment, the scan speed is approximately 300 mm/s. In an embodiment, an acceleration of the scan speed is a baseline of a given m/s². In an embodiment, the baseline is approximately 75 m/s².

The method 1700 then continues to block 1708 where a risk level is determined. The risk level of the pellicle may be determined using the parameters of block 1706. According to some embodiments, the risk level of the pellicle membrane 404 is determined based on a deformation level of the pellicle membrane 404. The deformation level of the pellicle membrane 404 may be provided by the inspection tool 203. Alternatively, the deformation level of the pellicle membrane 404 may be obtained from the inspection tool 203 through the database 316 in case the inspection tool 203 is not directly coupled to the photolithography apparatus 200. The risk levels of the pellicle membrane 404 are determined based on the parameters of block 1706, which may include, in addition to the deformation level of the pellicle membrane 404, at least one of an adjustment level of the radiation energy of the radiation source 324, a moving speed of the reticle stage 304, and a composition of the pellicle membrane 404. The determination of the risk level is discussed above.

The method 1700 then proceeds to block 1710 where it is determined if the pellicle is at high risk of rupture. In some embodiments, the determination includes determining a deformation level of the pellicle membrane 404. The determination may further include determining an adjustment level of the radiation energy. In some embodiments, in response to determination that the pellicle membrane 404 is at the high risk of rupture, the current pellicle membrane 404 is replaced with a new or qualified pellicle membrane 404 (step 1712), and the method 1700 proceeds back to the block 1706.

The method 1700 then proceeds to block 1714 where a medium risk is determined. If a medium risk is determined, in block 1716 a new scanning profile is developed to reduce the pressure on the reticle 402. As discussed above including with reference to FIG. 14, a scanning speed profile includes an acceleration section, a constant speed section, and a deceleration section. The acceleration section is at a beginning of a scanning path identified with the boundary points A and D. The constant speed section is subsequent to the acceleration (speed-up) section, and the deceleration (slow-down) section, which is subsequent to the constant speed section, is at an end of the scanning path. In the acceleration section, the scanning speed is increased from 0 to the second speed S2 with an acceleration value. The acceleration value may be kept substantially constant during the acceleration section in an embodiment. The acceleration value may be decreased in block 1716 to reduce the pressure on the reticle 402. In the constant speed section, the scanning speed is substantially fixed at the second speed S2. In the deceleration section, the scanning speed is reduced from the second speed S2 to 0 with a deceleration value. The deceleration value may be kept substantially constant during the deceleration section. The deceleration value may be decreased in block 1716 to reduce the pressure on the reticle 402. The method 1700 causes the reticle stage 304 to move according to the non-uniform scanning speed profile, which may mitigate undesirable air flow around the pellicle membrane 404, and the service life of the pellicle membrane 404 may be extended. In an embodiment, the acceleration/deceleration value may be decreased from the baseline (e.g., from 75 m/s² to 50 m/s²). In other embodiments, the baseline scan speed profile may include a constant speed including during the scan of the boundary regions 1004 of the reticle 402.

The method 1700 then proceeds to block 1718 where a low risk is determined. In response to determining that the pellicle membrane 404 is at the low risk of rupture, the baseline scanning profile may be maintained in block 1720. The scanning profile of block 1716 or 1720 is then used in block 1722 to perform a scanning exposure of a substrate (e.g., wafer) 320 provided to the exposure tool 202. The method 1700 may be repeated throughout the fabrication process and the lifetime of the reticle assembly and pellicle membrane.

In accordance with some embodiments of the present disclosure, a method is provided. The method includes steps of receiving a reticle assembly comprising a reticle and a pellicle membrane and transporting the reticle assembly to an exposure tool and securing the reticle assembly on a reticle stage of the exposure tool. The method includes determining a scanning speed profile based on a risk level associated with a quality of the pellicle membrane. And the method includes performing an exposure operation by driving the reticle stage according to the scanning speed profile.

In an embodiment, the method further includes measuring a deformation of the pellicle membrane to determine a sag value; and using the sag value to determine the scanning speed profile. In an implementation, determining scanning speed profile includes determining: an initial section at a beginning of a scanning path-the reticle stage is driven to move at a first acceleration in the initial section; a scanning section subsequent to the initial section-the reticle stage is driven at a substantially constant speed in the scanning section; and a final section subsequent to the scanning section at an end of the scanning path-the stage is driven to move at a first deceleration at the final section. In a further embodiment, determining the scanning speed profile includes decreasing a baseline acceleration to the first acceleration due to the risk level. And in some cases, the reticle comprises a feature region and a border region surrounding the feature region, and the scanning path begins at a lower boundary of the border region and terminates at an upper boundary of the border region.

In an embodiment, the pellicle membrane is determined to have the risk level based on at least one of a composition of the pellicle membrane, a deformation level of the pellicle membrane, an adjustment level of a radiation energy, a number of substrates processed, and a movement speed of a substrate stage for supporting a substrate to be exposed. And in a further embodiment, the method includes issuing an alarm signal when the adjustment level in the radiation energy is greater than a tolerable level. And in another further embodiment, the method includes driving of the reticle stage according to the scanning speed profile such that in response to the pellicle membrane being at a high risk of rupture, the pellicle membrane is replaced with a qualified pellicle membrane.

And in an embodiment, the method also includes detaching the reticle assembly from the reticle stage and transporting the reticle assembly to an inspection tool; irradiating an inspection beam onto the pellicle membrane and detecting scattered beams after the irradiation; and determining a deformation level of the pellicle membrane based on the detected scattered beams, wherein the risk level is determined using the deformation level. In a further embodiment, irradiating the inspection beam is performed during a polarity switch period of a reticle stage.

In accordance with some embodiments of the present disclosure, a method includes receiving a reticle assembly. The reticle assembly includes a reticle and a pellicle membrane. The reticle assembly is secured on a reticle stage of an exposure tool. The method further includes acquiring pellicle quality indices and determining a first scanning speed profile of the reticle stage based on the pellicle quality indices. An exposure operation is performed on a substrate according to the first scanning speed profile.

In an embodiment, the method includes acquiring the pellicle quality indices by an energy of power (EOP) status, wafer movement (W.M.) status, pellicle type, or deformation state of a pellicle film of the reticle assembly. And in some implementations, the method also includes replacing the pellicle membrane with a qualified pellicle membrane in response to the pellicle membrane being at a high risk of rupture. In an embodiment, acquiring pellicle quality indices includes receiving a sagging value from a measurement apparatus. And in some embodiments, acquiring pellicle quality indices includes measuring a deformation of a pellicle of the reticle assembly prior to the securing the reticle assembly on the reticle stage. In a further embodiment, the vacuum atmosphere is maintained between measuring the deformation and the securing the reticle assembly on the reticle stage. In an embodiment, the reticle assembly is secured on the reticle stage via an electrostatic chuck, and the measuring of the deformation of the pellicle membrane includes acquiring a sag value of the pellicle membrane during a polarity switch period of the electrostatic chuck.

In accordance with some embodiments of the present disclosure, also includes an apparatus having a radiation source configured to generate an electromagnetic radiation having a radiation energy. The electromagnetic radiation is guided to the reticle, and the reticle reflects and patterns the electromagnetic radiation to form a patterned electromagnetic radiation. The apparatus also includes a detector configured to acquire an exposure energy of the patterned electromagnetic radiation and generate a detection result. In some embodiments, the apparatus is further configured to tune the radiation energy according to the detection result and determine an adjustment level of the radiation energy.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a reticle assembly comprising a reticle and a pellicle membrane;
transporting the reticle assembly to an exposure tool and securing the reticle assembly on a reticle stage of the exposure tool;
acquiring operation parameters of the exposure tool;
determine a risk of the pellicle membrane rupturing;
performing at least one of determining a scanning speed profile or replacing the pellicle membrane based on the determined risk; and
performing an exposure operation by driving the reticle stage according to the scanning speed profile.

2. The method of claim 1, wherein determining the risk of the pellicle membrane includes determining an energy adjustment percentage (Eop).

3. The method of claim 2, wherein determining the Eop includes determining an Eop of greater than about 4.5%.

4. The method of claim 3, wherein based on the determined Eop, replacing the pellicle membrane.

5. The method of claim 1, wherein determining the Eop includes determining an Eop of less than about 4.5%.

6. The method of claim 5, wherein based on the determined Eop, determining a scanning speed profile.

7. The method of claim 1, wherein the determining scanning speed profile includes determining:
an initial section at a beginning of a scanning path, wherein the reticle stage is driven to move at a first acceleration in the initial section;
a scanning section subsequent to the initial section, wherein the reticle stage is driven at a substantially constant speed in the scanning section; and
a final section subsequent to the scanning section at an end of the scanning path, wherein the reticle stage is driven to move at first deceleration at the final section.

8. The method of claim 7, wherein the determining the scanning speed profile includes decreasing a baseline acceleration to the first acceleration due to the determined risk.

9. The method of claim 1, wherein the pellicle membrane is determined to have the risk based on at least one of a composition of the pellicle membrane, a deformation level of the pellicle membrane, an adjustment level of a radiation energy, a number of substrates processed, and a movement speed of a substrate stage for supporting a substrate to be exposed.

10. A method, comprising:
receiving a reticle assembly comprising a reticle and a pellicle membrane;
providing an exposure tool;
measuring a deformation of the pellicle membrane to determine a sag value;
using the sag value to determine a scanning speed profile for the exposure tool; and
performing an exposure operation by driving a reticle stage of the exposure tool according to the scanning speed profile.

11. The method of claim 10, wherein the determining the sag value includes:
transporting the reticle assembly to an inspection tool;
irradiating an inspection beam onto the pellicle membrane and detecting scattered beams after the irradiation; and
determining the sag value of the pellicle membrane based on the detected scattered beams.

12. The method of claim 10, wherein determining the sag value includes irradiating the inspection beam is performed during a polarity switch period of the reticle stage.

13. The method of claim 10, wherein the driving of the reticle stage according to the scanning speed profile further comprises:
in response to the pellicle membrane being at a high risk of rupture, replacing the pellicle membrane with a qualified pellicle membrane.

14. The method of claim 10, wherein a vacuum atmosphere is maintained between the determining the deformation and the performing the exposure operation.

15. A method, comprising:
receiving a reticle assembly, wherein the reticle assembly includes a reticle and a pellicle membrane;
securing the reticle assembly on a reticle stage of an exposure tool;
acquiring pellicle quality indices including at least one of energy of power (EOP) status, wafer movement (W.M.) status, pellicle type, or deformation;
determining a scanning speed profile of the reticle stage based on the pellicle quality indices; and
performing an exposure operation on a substrate according to the scanning speed profile.

16. The method of claim 15, wherein the acquiring pellicle quality indices includes deformation, and wherein the deformation is provided by a sagging value received from a measurement apparatus.

17. The method of claim 15, wherein the acquiring pellicle quality indices including acquiring the wafer movement (W.M.) status from process data.

18. The method of claim 15, wherein the determining scanning speed profile includes determining:
an initial section at a beginning of a scanning path, wherein the reticle stage is driven to move at a first acceleration in the initial section.

19. The method of claim 18, wherein the determining scanning speed profile further comprises:
a scanning section subsequent to the initial section, wherein the reticle stage is driven at a substantially constant speed in the scanning section.

20. The method of claim 18, wherein the determining scanning speed profile further comprises:
a final section subsequent to the scanning section at an end of the scanning path, wherein the reticle stage is driven to move at first deceleration at the final section.
